(19) United States
(12) Patent Application Publication
(10) Pub. No.: US 2026/0234507 A1
(43) Pub. Date: Aug. 13, 2026

(54) TREATMENT LIQUID, CLEANING METHOD FOR OBJECT TO BE TREATED, AND MANUFACTURING METHOD OF ELECTRONIC DEVICE

(71) Applicant: FUJIFILM CORPORATION, Tokyo (JP)

(72) Inventors: Atsushi Mizutani, Shizuoka (JP); Yuta Shigenoi, Shizuoka (JP); Shimpei Yamada, Shizuoka (JP)

(21) Appl. No.: 19/177,803

(22) Filed: Apr. 14, 2025

Related U.S. Application Data
(63) Continuation of application No. PCT/JP2023/041242, filed on Nov. 16, 2023.

(30) Foreign Application Priority Data
Dec. 8, 2022 (JP) 2022-196560

(51) Int. Cl. C11D 1/62; C11D 3/28; C11D 3/30; H10P 70/00

(52) U.S. Cl. CPC C11D 1/62; C11D 3/28; C11D 3/30; H10P 70/277

(57) ABSTRACT

An object is to provide a treatment liquid which can suppress an increase in surface roughness of a metal and has excellent defect removability on an object to be treated, in a case where the treatment liquid is applied onto an object to be treated containing a metal, which has been subjected to a chemical mechanical polishing treatment, after the treatment liquid is stored for a long period of time. The treatment liquid of the present invention is a treatment liquid used for an object to be treated, which has been subjected to a chemical mechanical polishing treatment, the treatment liquid containing a quaternary ammonium compound having no hydroxyl group, a tertiary alkylamine compound, a heterocyclic compound, and water, in which the tertiary alkylamine compound includes at least one or more tertiary alkylamine compounds having no hydroxyl group, and a mass ratio of a content of the tertiary alkylamine compound to a content of the heterocyclic compound is 10 to 400.

### CROSS-REFERENCE TO RELATED APPLICATIONS

This application is a Continuation of PCT International Application No. PCT/JP2023/041242 filed on Nov. 16, 2023, which claims priority under 35 U.S.C. § 119(a) to Japanese Patent Application No. 2022-196560 filed on Dec. 8, 2022. The above applications are hereby expressly incorporated by reference, in their entirety, into the present application.

### BACKGROUND OF THE INVENTION

### 1. Field of the Invention

The present invention relates to a treatment liquid, a cleaning method for an object to be treated, and a manufacturing method of an electronic device.

### 2. Description of the Related Art

In the field of semiconductors, with remarkable increase in integration and performance, even a very small amount of impurities (contamination) and/or attachments (particles) has a great influence on the performance of an apparatus and eventually the yield of a product.

In each manufacturing step of a semiconductor element, various contaminations and particles (hereinafter, also referred to as residues) may be generated. For example, as one step of manufacturing the semiconductor element, a chemical mechanical polishing treatment of flattening a surface of a semiconductor substrate having a metal wire film, a barrier metal, an insulating film, and the like using a polishing slurry containing abrasive particles (for example, silica, alumina, and the like) may be performed. In the chemical mechanical polishing treatment, the abrasive particles to be used in the chemical mechanical polishing treatment, a polished wiring line metal film, and/or a metal component derived from the barrier metal or the like easily remain on the surface of the semiconductor substrate after polishing. Therefore, after the chemical mechanical polishing treatment, a step of removing these residues using a treatment liquid is generally performed.

As the treatment liquid as described above, for example, JP2019-125804A discloses a cleaning liquid for a substrate of a semiconductor device having a barrier metal layer, which contains a compound having a specific structure, a pH adjuster containing a quaternary ammonium hydroxide having a specific structure, water, and citric acid.

### SUMMARY OF THE INVENTION

As a result of studying the cleaning liquid specifically disclosed in JP2019-125804A, the present inventors have found that, in a case where the cleaning liquid is applied onto an object to be treated containing a metal, which has been subjected to a chemical mechanical polishing treatment, after the cleaning liquid is stored for a long period of time, it is difficult to achieve both suppression of an increase in surface roughness of the metal and defect removability on the object to be treated.

An object of the present invention is to provide a treatment liquid which can suppress an increase in surface roughness of a metal and has excellent defect removability on an object to be treated, in a case where the treatment liquid is applied onto an object to be treated containing a metal, which has been subjected to a chemical mechanical polishing treatment, after the treatment liquid is stored for a long period of time.

Another object of the present invention is to provide a cleaning method for an object to be treated, using the above-described treatment liquid, and a manufacturing method of an electronic device.

As a result of conducting an extensive investigation to achieve the objects, the present inventors have found that the objects can be achieved by the following constitution.
[1] A treatment liquid used for an object to be treated, which has been subjected to a chemical mechanical polishing treatment, the treatment liquid comprising:
   a quaternary ammonium compound having no hydroxyl group;
   a tertiary alkylamine compound;
   a heterocyclic compound; and
   water,
   in which the tertiary alkylamine compound includes at least one or more tertiary alkylamine compounds having no hydroxyl group, and
   a mass ratio of a content of the tertiary alkylamine compound to a content of the heterocyclic compound is 10 to 400.
[2] The treatment liquid according to [1],
   in which a mass ratio of a content of the quaternary ammonium compound having no hydroxyl group to the content of the heterocyclic compound is 10 to 300.
[3] The treatment liquid according to [1] or [2],
   in which a pH is 10.0 to 14.0.
[4] The treatment liquid according to any one of [1] to [3],
   in which the treatment liquid substantially contains no abrasive particles.
[5] The treatment liquid according to any one of [1] to [4],
   in which the tertiary alkylamine compound has no cyclic structure.
[6] The treatment liquid according to any one of [1] to [5],
   in which the tertiary alkylamine compound has no oxygen atom.
[7] The treatment liquid according to any one of [1] to [6],
   in which the heterocyclic compound includes at least one selected from the group consisting of a purine compound, imidazole, pyrazole, thiazole, triazole, tetrazole, piperazine, pyrrole, indole, carbazole, quinoline, piperidine, pyridine, imidazoline, pyrimidine, and triazine.
[8] The treatment liquid according to any one of [1] to [7],
   in which the object to be treated, which has been subjected to a chemical mechanical polishing treatment, includes at least one metal selected from the group consisting of copper and cobalt.
[9] A cleaning method for an object to be treated, comprising:
   a step of cleaning an object to be treated, which has been subjected to a chemical mechanical polishing treatment, using the treatment liquid according to any one of [1] to [8].
[10] A manufacturing method of an electronic device, comprising:
   the cleaning method for an object to be treated according to [9].

According to the present invention, it is possible to provide a treatment liquid which can suppress an increase in surface roughness of a metal and has excellent defect removability on an object to be treated, in a case where the treatment liquid is applied onto an object to be treated containing a metal, which has been subjected to a chemical mechanical polishing treatment, after the treatment liquid is stored for a long period of time.

In addition, according to the present invention, it is possible to provide a cleaning method for an object to be treated, using the above-described treatment liquid, and a manufacturing method of an electronic device.

### DESCRIPTION OF THE PREFERRED EMBODIMENTS

Hereinafter, the present invention will be described in detail.

The description of the configuration requirements described below is made on the basis of representative embodiments of the present invention, but it should not be construed that the present invention is limited to those embodiments.

In the present specification, numerical ranges represented by “to” include numerical values before and after “to” as lower limit values and upper limit values.

In the present specification, “total mass of components in the treatment liquid excluding a solvent” means the total mass of all components contained in the treatment liquid other than a solvent such as water and an organic solvent.

In the present specification, in a case where there are two or more components corresponding to a certain component, “content” of such a component means the total content of the two or more components.

Unless otherwise specified, compounds described in the present specification may include structural isomers, optical isomers, and isotopes. In addition, one kind of structural isomer, optical isomer, and isotope may be included, or two or more kinds thereof may be included.

In the present specification, in a case of a plurality of substituents, linking groups, and the like (hereinafter, referred to as a substituent and the like) represented by specific reference numeral, or in a case of simultaneously defining a plurality of the substituent and the like, it means that each of the substituent and the like may be the same as or different with each other. The same applies to the definition of the number of substituents and the like.

A bonding direction of divalent groups cited in the present specification is not limited unless otherwise specified. For example, in a case where Y in a compound represented by Formula “X—Y—Z” is —COO—, Y may be —CO—O— or —O—CO—. In addition, the above-described compound may be “X—CO—O—Z” or “X—O—CO—Z”.

In the present specification, “ppm” means “parts-per-million (10⁻⁶)”, “ppb” means “parts-per-billion (10⁻⁹)”, “ppt” means “parts-per-trillion (10⁻¹²)”.

In the present specification, “weight-average molecular weight” means a weight-average molecular weight in terms of polyethylene glycol measured by gel permeation chromatography (GPC).

### [Treatment Liquid]

Hereinafter, the treatment liquid according to the embodiment of the present invention will be described in detail.

The treatment liquid according to the embodiment of the present invention (hereinafter, also simply referred to as “treatment liquid”) contains a quaternary ammonium compound having no hydroxyl group, a tertiary alkylamine compound, a heterocyclic compound, and water, in which the tertiary alkylamine compound includes at least one or more tertiary alkylamine compounds having no hydroxyl group, and a mass ratio of a content of the tertiary alkylamine compound to a content of the heterocyclic compound is 10 to 300.

The reason why the treatment liquid having the above-described configuration can achieve the object of the present invention is not necessarily clear, but the present inventors speculate as follows.

The mechanism by which the effect is obtained is not limited by the following supposition. In other words, even in a case where an effect is obtained by a mechanism other than the following, it is included in the scope of the present invention.

In a case where the treatment liquid contains a quaternary ammonium compound and a tertiary alkylamine compound, defect removability is excellent; and in a case where the treatment liquid contains a heterocyclic compound, a metal surface of the object to be treated is protected, and thus an increase in surface roughness of the metal can be suppressed. Furthermore, since the content ratio of the tertiary alkylamine compound to the heterocyclic compound is controlled within a certain range, the balance between the two characteristics can be appropriately adjusted.

Here, since the above-described quaternary ammonium compound has no hydroxyl group and the tertiary alkylamine compound includes a tertiary alkylamine compound having no hydroxyl group, the components of the treatment liquid are suppressed from being altered with time. As a result, the treatment liquid exhibits excellent characteristics even after being stored for a long period of time after preparation.

Hereinafter, the characteristic that the increase in surface roughness of the metal can be suppressed in a case where the treatment liquid is applied onto the object to be treated after being stored for a long period of time is also referred to as “surface roughness characteristic after long-term storage”. In addition, the defect removability in a case where the treatment liquid is applied onto the object to be treated after being stored for a long period of time is also simply referred to as “defect removability after long-term storage”.

The fact that at least one selected from the surface roughness characteristic after long-term storage or the defect removability after long-term storage is more excellent is also referred to as “effect of the present invention is more excellent”.

### [Quaternary Ammonium Compound Having No Hydroxyl Group]

The treatment liquid contains a quaternary ammonium compound having no hydroxyl group.

The quaternary ammonium compound is preferably a compound having a quaternary ammonium cation in which a nitrogen atom is substituted with four hydrocarbon groups (preferably, alkyl groups). In addition, the quaternary ammonium compound may be a compound having a quaternary ammonium cation in which a nitrogen atom in a pyridine ring is bonded to a substituent (a hydrocarbon group such as an alkyl group and an aryl group), for example, an alkyl pyridinium.

Examples of the quaternary ammonium compound include a quaternary ammonium hydroxide, a quaternary ammonium acetate, and a quaternary ammonium carbonate.

The quaternary ammonium compound having no hydroxyl group is preferably a compound represented by Formula (A).

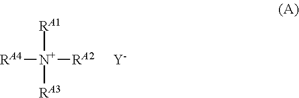

In Formula (A), R^{A1} to R^{A4} each independently represent a hydrocarbon group which may have a substituent other than a hydroxyl group.

Examples of the substituent other than a hydroxyl group, which may be included in the above-described hydrocarbon group, include a halogen atom such as a fluorine atom, a chlorine atom, and a bromine atom, an alkyl group, an alkoxy group, an alkoxycarbonyl group such as a methoxycarbonyl group and an ethoxycarbonyl group, an acyl group such as an acetyl group, a propionyl group, and benzoyl group, a cyano group, a nitro group, a thiol group, and a dioxiranyl group.

In a case where the above-described hydrocarbon group has a substituent, the number of substituents is preferably 1 to 5, more preferably 1 to 3, and still more preferably 1.

The number of carbon atoms in the above-described hydrocarbon group is preferably 1 to 20, more preferably 1 to 10, still more preferably 1 to 5, and particularly preferably 1 to 3.

Examples of the above-described hydrocarbon group include an alkyl group, an alkenyl group, an alkynyl group, an aryl group, and a group obtained by combining these groups.

The above-described alkyl group may be linear, branched, or cyclic. The number of carbon atoms in the above-described alkyl group is preferably 1 to 20, more preferably 1 to 10, still more preferably 1 to 5, and particularly preferably 1 to 3.

Examples of the above-described alkyl group include a methyl group, an ethyl group, an n-propyl group, an isopropyl group, an n-butyl group, and a t-butyl group; and a methyl group, an ethyl group, an n-propyl group, or an isopropyl group is preferable, and a methyl group or an ethyl group is more preferable.

The alkenyl group and alkynyl group described above may be linear, branched, or cyclic. The number of carbon atoms in the alkenyl group and alkynyl group described above is preferably 2 to 20, more preferably 2 to 10, and still more preferably 2 to 5.

Examples of the alkenyl group and alkynyl group described above include a vinyl group, an allyl group, an ethynyl group, and a propargyl group.

The above-described aryl group may be monocyclic or polycyclic. The number of carbon atoms in the above-described aryl group is preferably 6 to 20, more preferably 6 to 10, and still more preferably 6 to 8.

Examples of the above-described aryl group include a benzyl group, a phenyl group, a naphthyl group, an anthryl group, a phenanthryl group, an indenyl group, an acenaphthenyl group, a fluorenyl group, and a pyrenyl group; and a benzyl group or a phenyl group is preferable, and a phenyl group is more preferable.

As the group represented by R^{A1} to R^{A4}, the alkyl group or the aryl group is preferable, the alkyl group is more preferable, and a linear or branched alkyl group having 1 to 5 carbon atoms is still more preferable.

It is also preferable that three or more of R^{A1} to R^{A4} represent the same group. For example, it is preferable that R^{A1} to R^{A3} represent a methyl group and R^{A4} represents an ethyl group, and it is also preferable that all of R^{A1} to R^{A4} represent a methyl group.

The total number of carbon atoms in the groups represented by R^{A1} to R^{A4} is not particularly limited, but is 4 or more, preferably 4 to 30, more preferably 4 to 25, still more preferably 4 to 15, and particularly preferably 5 to 10.

Y⁻ represents an anion.

Examples of the anion include acid anions such as a carboxylate ion, a phosphate ion, a phosphonate ion, and a nitrate ion, and a hydroxide ion; and a hydroxide ion is preferable.

Examples of the quaternary ammonium compound having no hydroxyl group include tetramethylammonium hydroxide (TMAH), ethyltrimethylammonium hydroxide (ETMAH), tetraethylammonium hydroxide (TEAH), dimethyldiethylammonium hydroxide, methyltriethylammonium hydroxide (MTEAH), tetrapropylammonium hydroxide (TPAH), tetrabutylammonium hydroxide (TBAH), benzyltrimethylammonium hydroxide (BTMAH), and cetyltrimethylammonium hydroxide; and TMAH, ETMAH, or TEAH is preferable.

The quaternary ammonium compound having no hydroxyl group may be used alone, or two or more types thereof may be used in combination.

From the viewpoint that the effect of the present invention is more excellent, a content of the quaternary ammonium compound having no hydroxyl group is 0.001% to 10.0% by mass, more preferably 0.005% to 7.0% by mass, and still more preferably 0.01% to 5.0% by mass with respect to the total mass of the treatment liquid.

The content of the quaternary ammonium compound having no hydroxyl group is preferably 1.0% to 90.0% by mass, more preferably 3.0% to 80.0% by mass, and still more preferably 5.0% to 75.0% by mass with respect to the total mass of all components of the treatment liquid excluding a solvent.

### [Tertiary Alkylamine Compound]

The treatment liquid contains a tertiary alkylamine compound.

The tertiary alkylamine compound includes at least one tertiary alkylamine compound having no hydroxyl group. The tertiary alkylamine compound may further include one or more tertiary alkylamine compounds which may have a hydroxyl group.

The tertiary alkylamine compound is a compound having at least one tertiary amino group (>N—) in which three alkyl groups are substituted on a nitrogen atom.

The above-described alkyl group may be linear, branched, or cyclic, and is preferably linear or branched. The number of carbon atoms in the above-described alkyl group is preferably 1 to 20, more preferably 1 to 12, and still more preferably 1 to 6.

The above-described alkyl groups may be bonded to each other to form a cyclic structure. That is, the tertiary alkylamine compound may have a cyclic structure in which the nitrogen atom of the tertiary amino group is to be a ring member atom. The above-described ring is a non-aromatic ring.

In addition, the above-described ring may further include an oxygen atom or a nitrogen atom as a ring member atom.

The number of ring member atoms in the above-described ring is preferably 3 to 10, more preferably 4 to 8, and still more preferably 5 or 6.

From the viewpoint that the effect of the present invention is more excellent, it is preferable that the tertiary alkylamine compound does not have a cyclic structure.

The tertiary alkylamine compound may have two or more tertiary amino groups in the molecule. In other words, the above-described alkyl group may have the tertiary amino group as a substituent.

The number of tertiary amino groups included in the tertiary alkylamine compound is 1 or more, preferably 1 to 6 and more preferably 1 to 3.

The tertiary alkylamine compound may have a substituent. As the substituent, a hydroxyl group, a primary amino group, a secondary amino group, a tertiary amino group, a carboxy group, a phosphonate group, or a sulfonate group is preferable, and a primary amino group, a secondary amino group, or a tertiary amino group is more preferable.

In a case where the tertiary alkylamine compound has a substituent, the number of substituents is not particularly limited, but is preferably 1 to 6 and more preferably 1 to 3.

The tertiary alkylamine compound may have an ether bond in the molecule. In a case where the tertiary alkylamine compound has an ether bond in the molecule, the number of ether bonds is not particularly limited, but is preferably 1 to 3 and more preferably 1. In addition, from the viewpoint that the effect of the present invention is more excellent, it is preferable that the tertiary alkylamine compound does not have an ether bond in the molecule.

It is sufficient that the number of nitrogen atoms in the tertiary alkylamine compound is 1 or more, preferably 2 or more. The upper limit thereof is not particularly limited, but is preferably 6 or less, more preferably 4 or less, and still more preferably 3 or less.

The number of oxygen atoms in the tertiary alkylamine compound is preferably 0 to 3, more preferably 0 or 1, and still more preferably 0. That is, it is preferable that the tertiary alkylamine compound does not have an oxygen atom.

The number of carbon atoms in the tertiary alkylamine compound is 3 or more, and is preferably 3 to 20, more preferably 4 to 12, and still more preferably 6 to 10.

A molecular weight of the tertiary alkylamine compound is preferably 50 to 300 and more preferably 70 to 200.

Examples of the tertiary alkylamine compound include a compound represented by Formula (B1) and a compound represented by Formula (B2).

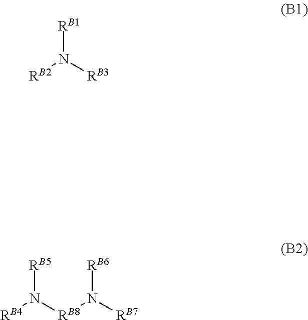

In Formula (B1), R^{B1} to R^{B3} each independently represent an alkyl group which may have a substituent and may have an ether bond.

The above-described alkyl group may be linear, branched, or cyclic, and is preferably linear or branched. The number of carbon atoms in the above-described alkyl group is preferably 1 to 20, more preferably 1 to 12, and still more preferably 1 to 6.

Examples of the substituent which may be included in the alkyl group represented by R^{B1} to R^{B3} include a hydroxyl group and an —NHR^{N} group.

R^{N} represents a hydrogen atom or an alkyl group. For example, in a case where R^{N} is a hydrogen atom, the —NHR^{N} group represents a primary amino group; and in a case where R^{N} is an alkyl group, the —NHR^{N} group represents a secondary amino group.

The above-described alkyl group represented by R^{N} may be linear, branched, or cyclic, and is preferably linear or branched. The number of carbon atoms in the above-described alkyl group is preferably 1 to 10, more preferably 1 to 6, and still more preferably 1 to 3.

R^{N} is preferably a hydrogen atom or an alkyl group having 1 to 3 carbon atoms, and more preferably a hydrogen atom or a methyl group.

In a case where a plurality of R^{N}'s are present, the groups represented by the plurality of R^{N}'s may be the same or different from each other.

In a case where the alkyl group represented by R^{B1} to R^{B3} has a substituent, the number of substituents is not particularly limited, but is preferably 1 to 3 and more preferably 1.

In a case where the alkyl group represented by R^{B1} to R^{B3} has an ether bond, the number of ether bonds is not particularly limited, but is preferably 1 to 3 and more preferably 1. From the viewpoint that the effect of the present invention is more excellent, it is preferable that the above-described alkyl group does not have an ether bond.

In Formula (B2), R^{B4} to R^{B7} each independently represent an alkyl group which may have a substituent and may have an ether bond.

The above-described alkyl group may be linear, branched, or cyclic, and is preferably linear or branched. The number of carbon atoms in the above-described alkyl group is preferably 1 to 20, more preferably 1 to 12, still more preferably 1 to 6, and particularly preferably 1 to 3.

Examples of the substituent which may be included in the alkyl group represented by R^{B4} to R^{B7} include a hydroxyl group and an —NHR^{N} group.

The definition and preferred aspect of R^{N} are as described above.

In a case where a plurality of R^{N}'s are present, the groups represented by the plurality of R^{N}'s may be the same or different from each other.

In a case where the alkyl group represented by R^{B4} to R^{B7} has a substituent, the number of substituents is not particularly limited, but is preferably 1 to 3 and more preferably 1.

In a case where the alkyl group represented by R^{B4} to R^{B7} has an ether bond, the number of ether bonds is not particularly limited, but is preferably 1 to 3 and more preferably 1. From the viewpoint that the effect of the present invention is more excellent, it is preferable that the above-described alkyl group does not have an ether bond.

R^{B8} represents an alkylene group which may have a substituent, may have a divalent linking group represented by —NR^{N}—, and may have an ether bond.

The definition and preferred aspect of R^{N} are as described above.

In a case where a plurality of R^{N}'s are present, the groups represented by the plurality of R^{N}'s may be the same or different from each other.

The above-described alkylene group may be linear, branched, or cyclic, and is preferably linear or branched. The number of carbon atoms in the above-described alkylene group is preferably 1 to 20, more preferably 1 to 12, and still more preferably 1 to 6.

Examples of the substituent which may be included in the alkylene group represented by R^{B8} include a hydroxyl group and an —NHR^{N} group.

The definition and preferred aspect of R^{N} are as described above.

In a case where a plurality of R^{N}'s are present, the groups represented by the plurality of R^{N}'s may be the same or different from each other.

In a case where the above-described alkylene group has a divalent linking group represented by —NR^{N}—, the number of divalent linking groups represented by —NR^{N}— is not particularly limited, but is preferably 1 to 3 and more preferably 1.

In a case where the above-described alkylene group has an ether bond, the number of ether bonds is not particularly limited, but is preferably 1 to 3 and more preferably 1. From the viewpoint that the effect of the present invention is more excellent, it is preferable that the above-described alkylene group does not have an ether bond.

The tertiary alkylamine compound may be a compound represented by Formula (B3). The compound represented by Formula (B3) is a tertiary alkylamine compound having a cyclic structure.

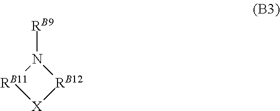

In Formula (B3), R^{B9} represents an alkyl group which may have a substituent and may have an ether bond.

The alkyl group represented by R^{B9} may be linear, branched, or cyclic, and is preferably linear or branched. The number of carbon atoms in the above-described alkyl group is preferably 1 to 20, more preferably 1 to 12, and still more preferably 1 to 6.

Examples of the substituent which may be included in the alkyl group represented by R^{B9} include a hydroxyl group and an —NR^{N}₂ group.

The definition and preferred aspect of R^{N} are as described above.

In a case where both of two R^{N}'s are hydrogen atoms, the —NR^{N}₂ group represents a primary amino group; in a case where one R^{N} is a hydrogen atom and the other R^{N} is an alkyl group, the —NR^{N}₂ group represents a secondary amino group; and in a case where both of two R^{N}'s are alkyl groups, the —NR^{N}₂ group represents a tertiary amino group. A plurality of groups represented by R^{N} may be the same or different from each other.

In a case where the alkyl group represented by R^{B9} has a substituent, the number of substituents is not particularly limited, but is preferably 1 to 3 and more preferably 1.

In a case where the alkyl group represented by R^{B9} has an ether bond, the number of ether bonds is not particularly limited, but is preferably 1 to 3 and more preferably 1. From the viewpoint that the effect of the present invention is more excellent, it is preferable that the above-described alkyl group does not have an ether bond.

X represents a single bond or a divalent linking group represented by -(L-NR^{B10})ₙ—.

L represents a single bond or an alkylene group.

The above-described alkylene group may be linear, branched, or cyclic, and is preferably linear or branched. The number of carbon atoms in the above-described alkylene group is preferably 1 to 12, more preferably 1 to 6, and still more preferably 1 to 3.

R^{B10} represents a hydrogen atom or an alkyl group which may have a substituent and may have an ether bond.

The alkyl group represented by R^{B10} may be linear, branched, or cyclic, and is preferably linear or branched. The number of carbon atoms in the above-described alkyl group is preferably 1 to 20, more preferably 1 to 12, and still more preferably 1 to 6.

Examples of the substituent which may be included in the alkyl group represented by R^{B10} include a hydroxyl group and an —NR^{N}₂ group.

The definition and preferred aspect of R^{N} are as described above.

A plurality of groups represented by R^{N} may be the same or different from each other.

In a case where the alkyl group represented by R^{B10} has a substituent, the number of substituents is not particularly limited, but is preferably 1 to 3 and more preferably 1.

In a case where the alkyl group represented by R^{B10} has an ether bond, the number of ether bonds is not particularly limited, but is preferably 1 to 3 and more preferably 1. From the viewpoint that the effect of the present invention is more excellent, it is preferable that the above-described alkyl group does not have an ether bond.

In a case where a plurality of R^{B10}'s are present, the groups represented by the plurality of R^{B10}'s may be the same or different from each other.

The alkyl groups represented by R^{B9} and R^{B10} may be linked to each other to form a ring.

n represents 1 or 2, preferably 1.

R^{B11} and R^{B12} each independently represent an alkylene group which may have a substituent and may have an ether bond.

The above-described alkylene group may be linear, branched, or cyclic, and is preferably linear or branched. The number of carbon atoms in the above-described alkylene group is preferably 1 to 12, more preferably 1 to 6, and still more preferably 2 to 5.

Examples of the substituent which may be included in the above-described alkylene group include a hydroxyl group and an —NR^{N}₂ group.

The definition and preferred aspect of R^{N} are as described above.

A plurality of groups represented by R^{N} may be the same or different from each other.

In a case where the above-described alkylene group has a substituent, the number of substituents is not particularly limited, but is preferably 1 to 3 and more preferably 1.

In a case where the above-described alkylene group has an ether bond, the number of ether bonds is not particularly limited, but is preferably 1 to 3 and more preferably 1. From the viewpoint that the effect of the present invention is more excellent, it is preferable that the above-described alkyl group does not have an ether bond.

The total number of carbon atoms in the alkylene group represented by R^{B11} and the alkylene group represented by R^{B12} is 2 or more, and is preferably 2 to 10, more preferably 2 to 6, and still more preferably 4 or 5.

Examples of the compound represented by Formula (B3) include a piperidine compound and a piperazine compound.

As the tertiary alkylamine compound, the compounds represented by Formula (B1) to Formula (B3) are preferable; the compound represented by Formula (B1) or the compound represented by Formula (B2) is more preferable; and the compound represented by Formula (B1) having no hydroxyl group or the compound represented by Formula (B2) having no hydroxyl group is still more preferable.

The compound represented by Formula (B1) having no hydroxyl group is more specifically a compound in which R^{B1} to R^{B3} are each independently an alkyl group which may have a substituent other than a hydroxyl group and may have an ether bond.

In addition, the compound represented by Formula (B2) having no hydroxyl group is more specifically a compound in which R^{B4} to R^{B7} are each independently an alkyl group which may have a substituent other than a hydroxyl group and may have an ether bond, and R^{B8} is an alkylene group which may have a substituent other than a hydroxyl group, may have a divalent linking group represented by —NR^{N}—, and may have an ether bond.

The tertiary alkylamine compound may be used alone, or two or more types thereof may be used in combination.

From the viewpoint that the effect of the present invention is more excellent, a content of the tertiary alkylamine compound is 0.001% to 8.0% by mass, more preferably 0.005% to 5.0% by mass, and still more preferably 0.01% to 3.0% by mass with respect to the total mass of the treatment liquid.

The content of the tertiary alkylamine compound is preferably 5.0% to 98.0% by mass, more preferably 15.0% to 95.0% by mass, and still more preferably 20.0% to 93.0% by mass with respect to the total mass of all components of the treatment liquid excluding a solvent.

A mass ratio of the content of the tertiary alkylamine compound to the content of the quaternary ammonium compound having no hydroxyl group is preferably 0.1 to 50, more preferably 0.2 to 30, and still more preferably 0.3 to 15.

### <Tertiary Alkylamine Compound Having No Hydroxyl Group>

The tertiary alkylamine compound includes a tertiary alkylamine compound having no hydroxyl group.

Examples of the tertiary alkylamine compound having no hydroxyl group include the compound represented by Formula (B1) having no hydroxyl group, the compound represented by Formula (B2) having no hydroxyl group, and the compound represented by Formula (B3) having no hydroxyl group.

The compound represented by Formula (B3) having no hydroxyl group is more specifically a compound in which R^{B9} and R^{B10} are each independently an alkyl group which may have a substituent other than a hydroxyl group and may have an ether bond, and R^{B11} and R^{B12} are each independently an alkylene group which may have a substituent other than a hydroxyl group and may have an ether bond.

Examples of the compound represented by Formula (B1) having no hydroxyl group include trialkyltriamine compounds such as trimethylamine, triethylamine (TEA), tripropylamine, triisopropylamine, tributylamine, N,N-dimethylethylamine, N,N-diisopropylethylamine, N,N-dimethylpropylamine, N,N-diethylpropylamine, N,N-diethylbutylamine, N,N-dipropylmethylamine, N,N-dipropylbutylamine, N,N-dibutylmethylamine, and N,N-dibutylethylamine.

Examples of the compound represented by Formula (B1) other than the above-described compounds include polyamine compounds such as tris(2-aminoethyl)amine, N,N-dimethylethylenediamine, and 2-(diethylamino)ethylamine.

Examples of the compound represented by Formula (B2) having no hydroxyl group include alkylene diamine compounds such as N,N,N′,N′-tetramethylethylenediamine, N,N,N′,N′-tetramethylhexamethylenediamine, bis(2-dimethylaminoethyl)ether, 1,3-bis(dimethylamino)butane, and N,N,N′,N′-tetramethyl-1,3-propanediamine, and polyalkylpolyamine compounds such as N,N,N′,N″,N″-pentamethyldiethylenetriamine (PMDETA) and N,N,N′,N″,N″-pentamethyldipropylenetriamine.

Examples of the compound represented by Formula (B3) having no hydroxyl group include piperidine compounds such as N-methylpiperidine and N-ethylpiperidine, and piperazine compounds such as 1,4-dimethylpiperazine, 1,4-bis(2-aminoethyl)piperazine, 1,4-bis(3-aminopropyl)piperazine, N-methyl-N′-(2-dimethylaminoethyl)piperazine, N-(2-aminoethyl)piperazine (AEP), 1-methylpiperazine, 1-ethylpiperazine, 1-propylpiperazine, and 1-butylpiperazine.

The tertiary alkylamine compound having no hydroxyl group is preferably the compound represented by Formula (B1) having no hydroxyl group or the compound represented by Formula (B2) having no hydroxyl group.

Among these, as the tertiary alkylamine compound having no hydroxyl group, PMDETA, N,N,N′,N′-tetramethylethylenediamine, TEA, bis(2-dimethylaminoethyl)ether, N,N,N′,N′-tetramethylhexamethylenediamine, N-methyl-N′-(2-dimethylaminoethyl)piperazine, N-methylpiperidine, N,N-diisopropylethylamine, N,N-dimethylethylenediamine, or tris(2-aminoethyl)amine is preferable; and PMDETA, N,N,N′,N′-tetramethylethylenediamine, TEA, N,N,N′,N′-tetramethylhexamethylenediamine, N,N-diisopropylethylamine, N,N-dimethylethylenediamine, or tris(2-aminoethyl)amine is more preferable.

The tertiary alkylamine compound having no hydroxyl group may be used alone, or two or more types thereof may be used in combination.

A content of the tertiary alkylamine compound having no hydroxyl group is preferably 0.001% to 8.0% by mass, more preferably 0.002% to 5.0% by mass, and still more preferably 0.005% to 3.0% by mass with respect to the total mass of the treatment liquid.

The content of the tertiary alkylamine compound having no hydroxyl group is preferably 1.0% to 95.0% by mass, more preferably 3.0% to 90.0% by mass, and still more preferably 4.0% to 85.0% by mass with respect to the total mass of all components of the treatment liquid excluding a solvent.

The content of the tertiary alkylamine compound having no hydroxyl group is more than 0% by mass, preferably 3% by mass or more, more preferably 50% by mass or more, and still more preferably 70% by mass or more with respect to the content of the tertiary alkylamine compound. The upper limit thereof is not particularly limited, and is 100% by mass.

### <Tertiary Alkylamine Compound Having Hydroxyl Group>

The tertiary alkylamine compound may include a tertiary alkylamine compound having a hydroxyl group.

Examples of the tertiary alkylamine compound having a hydroxyl group include the compound represented by Formula (B1) having a hydroxyl group, the compound represented by Formula (B2) having a hydroxyl group, and the compound represented by Formula (B3) having a hydroxyl group.

The compound represented by Formula (B1) having a hydroxyl group is more specifically a compound in which at least one of R^{B1} to R^{B3} is an alkyl group which has a hydroxyl group and may have an ether bond.

In addition, the compound represented by Formula (B2) having a hydroxyl group is more specifically a compound in which at least one of R^{B4} to R^{B7} is an alkyl group which has a hydroxyl group and may have an ether bond, or R^{B8} is an alkylene group which has a hydroxyl group, and may have a divalent linking group represented by —NR^{N}— or may have an ether bond.

The compound represented by Formula (B3) having a hydroxyl group is more specifically a compound in which at least one of R^{B9} or R^{B10} is an alkyl group which has a hydroxyl group and may have an ether bond, or at least one of R^{B11} or R^{B12} is an alkylene group which has a hydroxyl group and may have an ether bond.

Examples of the compound represented by Formula (B1) having a hydroxyl group include 2-(dimethylamino)-2-methyl-1-propanol (DMAMP), N,N-dimethylaminoethoxyethanol, 2-(dimethylamino)ethanol (DMAE), N-methyldiethanolamine (MDEA), 2-(diethylamino)ethanol, N-ethyldiethanolamine (EDEA), 2-(dibutylamino)ethanol, 2-[2-(dimethylamino)ethoxy]ethanol, triethanolamine, and N-butyldiethanolamine (BDEA).

Examples of the compound represented by Formula (B3) having a hydroxyl group include 3-hydroxy-1-methylpiperidine, 1,4-bis(2-hydroxyethyl)piperazine, and 1-(2-hydroxyethyl)piperazine (HEP).

As the tertiary alkylamine compound having a hydroxyl group, the compound represented by Formula (B1) having a hydroxyl group or the compound represented by Formula (B3) having a hydroxyl group is preferable, and the compound represented by Formula (B1) having a hydroxyl group is more preferable.

Among these, 2-(dimethylamino)-2-methyl-1-propanol, N,N-dimethaminoethoxyethanol, or 3-hydroxy-1-methylpiperidine is preferable; and 2-(dimethylamino)-2-methyl-1-propanol or N,N-dimethaminoethoxyethanol is more preferable.

The tertiary alkylamine compound having a hydroxyl group may be used alone, or two or more types thereof may be used in combination.

In a case where the treatment liquid contains the tertiary alkylamine compound having a hydroxyl group, a content thereof is preferably 0.0001% to 0.5% by mass, and more preferably 0.0005% to 0.1% by mass with respect to the total mass of the treatment liquid.

It is also preferable that the treatment liquid does not substantially contain the tertiary alkylamine compound having a hydroxyl group. The expression “does not substantially contain the tertiary alkylamine compound having a hydroxyl group” means that the content of the tertiary alkylamine compound having a hydroxyl group is 1% by mass or less, preferably 0.1% by mass or less, more preferably 0.01% by mass or less with respect to the content of the tertiary alkylamine compound; and the lower limit thereof is 0% by mass.

### [Heterocyclic Compound]

The heterocyclic compound is a compound having a heterocyclic structure in the molecule. The heterocyclic compound is a component different from each of the above-described components (the quaternary ammonium compound having no hydroxyl group and the tertiary alkylamine compound).

Examples of a heteroatom included in the above-described heterocyclic structure include a nitrogen atom, a sulfur atom, an oxygen atom, and a phosphorus atom.

The heterocyclic compound is preferably a compound which functions as a corrosion inhibitor for a metal included in the object to be treated, which will be described later.

The above-described heterocyclic compound may be monocyclic or polycyclic.

The heterocyclic compound may be an aliphatic heterocyclic compound or an aromatic heterocyclic compound, and an aromatic heterocyclic compound is preferable.

Examples of the heterocyclic compound include a purine compound and an azole compound, and a purine compound is preferable.

### <Purine Compound>

The purine compound represents purine or a purine derivative.

Examples of the purine compound include xanthine, adenine, adenosine, guanine, hypoxanthine, uric acid, purine, caffeine, isoguanine, theobromine, theophylline, paraxanthine, kinetin, enprofylline, xanthosine, 7-methylxanthosine, 7-methylxanthine, eritadenine, 3-methyladenine, 3-methylxanthine, 1,7-dimethylxanthine, 1-methylxanthine, 1,3-dipropyl-7-methylxanthine, 3,7-dihydro-7-methyl-1H-purine-2,6-dione, 1,7-dipropyl-3-methylxanthine, 1-methyl-3,7-dipropylxanthine, 1,3-dipropyl-7-methyl-8-dicyclopropylmethylxanthine, 1,3-dibutyl-7-(2-oxopropyl)xanthine, 1-butyl-3,7-dimethylxanthine, 3,7-dimethyl-1-propylxanthine, mercaptopurine, 2-aminopurine, 6-aminopurine, 6-benzylaminopurine, nelarabine, vidarabine, 2,6-dichloropurine, acyclovir, N⁶-benzoyl adenosine, trans-zeatin, entecavir, valacyclovir, abacavir, 2′-deoxyguanosine, disodium inosinate, ganciclovir, disodium guanosine 5′-monophosphate, O-cyclohexylmethylguanine, N 2-isobutyryl-2′-deoxyguanosine, β-nicotinamide adenine dinucleotide phosphate, 6-chloro-9-(tetrahydropyran-2-yl)purine, clofarabine, 7-(2,3-dihydroxypropyl)theophylline, 6-mercaptopurine, proxyphylline, 2,6-diaminopurine, 2′,3′-dideoxyinosine, theophylline-7-acetate, 2-chloroadenine, 2-amino-6-chloropurine, 8-bromo-3-methylxanthine, 2-fluoroadenine, penciclovir, 9-(2-hydroxyethyl)adenine, 7-(2-chloroethyl)theophylline, 2-amino-6-iodopurine, 2-thioxanthine, 2-amino-6-methoxypurine, N-acetylguanine, adefovir pivoxil, 8-chlorotheophylline, 6-methoxypurine, 1-(3-chloropropyl)theobromine, 6-(dimethylamino)purine, inosine, and derivatives thereof.

Among these, as the purine compound, xanthine, adenine, adenosine, guanine, hypoxanthine, uric acid, purine, caffeine, isoguanine, theobromine, theophylline, or paraxanthine is preferable; and xanthine, adenine, or adenosine is more preferable.

### <Azole Compound>

The azole compound is a compound having an aromatic heterocyclic 5-membered ring including a nitrogen atom.

The number of nitrogen atoms included in the aromatic heterocyclic 5-membered ring of the azole compound is preferably 1 to 4 and more preferably 1 to 3.

The azole compound may have a substituent on the aromatic heterocyclic 5-membered ring. Examples of the above-described substituent include a hydroxyl group, a carboxy group, a mercapto group, an amino group, an alkyl group having 1 to 4 carbon atoms, which may have an amino group, and a 2-imidazolyl group.

Examples of the azole compound include pyrrole in which one of atoms constituting the azole ring is a nitrogen atom, an imidazole compound and a pyrazole compound, in which two of atoms constituting an azole ring are nitrogen atoms, a thiazole compound in which one of atoms constituting an azole ring is a nitrogen atom and the other is a sulfur atom, a triazole compound in which three of atoms constituting an azole ring are nitrogen atoms, and a tetrazole compound in which four of atoms constituting an azole ring are nitrogen atoms.

Examples of the imidazole compound include imidazole, 1-methylimidazole, 2-methylimidazole, 5-methylimidazole, 1,2-dimethylimidazole, 2-mercaptoimidazole, 4,5-dimethyl-2-mercaptoimidazole, 4-hydroxyimidazole, 2,2′-biimidazole, 4-imidazolecarboxylic acid, histamine, benzimidazole, and derivatives thereof; and benzimidazole is preferable.

Examples of the pyrazole compound include 2,4-dimethylthiazole, 3,5-dimethylpyrazole, benzothiazole, 2-mercaptobenzothiazole, and derivatives thereof; and 3,5-dimethylpyrazole is preferable.

Examples of the thiazole compound include 2,4-dimethylthiazole, benzothiazole, 2-mercaptobenzothiazole, and derivatives thereof.

Examples of the triazole compound include 1,2,4-triazole, 3-methyl-1,2,4-triazole, 3-amino-1,2,4-triazole, 1,2,3-triazole, 1-methyl-1,2,3-triazole, benzotriazole, 1-hydroxybenzotriazole, 1-dihydroxypropylbenzotriazole, 2,3-dicarboxypropylbenzotriazole, 4-hydroxybenzotriazole, 4-carboxybenzotriazole, 5-methylbenzotriazole, and 2,2′-{[(5-methyl-1H-benzotriazole-1-yl)methyl]imino}diethanol, and derivatives thereof; and 1,2,3-triazole is preferable.

Examples of the tetrazole compound include 1H-tetrazole (1,2,3,4-tetrazole), 5-methyltetrazole, 5-aminotetrazole, 1,5-pentamethylenetetrazole, 1-phenyl-5-mercaptotetrazole, 1-(2-dimethylaminoethyl)-5-mercaptotetrazole, and derivatives thereof; and 5-aminotetrazole is preferable.

As the azole compound, a triazole compound, a tetrazole compound, an imidazole compound, or a pyrazole compound is preferable; and imidazole, pyrazole, thiazole, triazole, tetrazole, or pyrrole is more preferable.

Examples of the heterocyclic compound other than those described above include aromatic heterocyclic compounds such as indole, quinoline, pyridine, pyrimidine, carbazole, and triazine, and aliphatic heterocyclic compounds such as piperazine, piperidine, imidazoline, and derivatives thereof.

The heterocyclic compound may be used alone, or two or more types thereof may be used in combination.

A mass ratio of the content of the tertiary alkylamine compound to a content of the heterocyclic compound is 10 to 300. In a case where the mass ratio of the content of the tertiary alkylamine compound to the content of the heterocyclic compound is less than 10, the defect removability is deteriorated; and in a case where the mass ratio is more than 300, the surface roughness characteristic after long-term storage is deteriorated, which is not preferable.

From the viewpoint that the effect of the present invention is more excellent, the mass ratio of the content of the tertiary alkylamine compound to the content of the heterocyclic compound is preferably 200 or less, and more preferably 150 or less. The lower limit of the above-described mass ratio is preferably 15 or more, more preferably 20 or more, and still more preferably 30 or more.

From the viewpoint that the effect of the present invention is more excellent, a mass ratio of the content of the quaternary ammonium compound having no hydroxyl group to the content of the heterocyclic compound is preferably 300 or less, more preferably 200 or less, and still more preferably 100 or less. From the viewpoint that the effect of the present invention is more excellent, the lower limit of the above-described mass ratio is preferably 5 or more, more preferably 10 or more, still more preferably 15 or more, particularly preferably 20 or more, and most preferably 30 or more.

From the viewpoint that the effect of the present invention is more excellent, a content of the heterocyclic compound is 0.00001% to 1.0% by mass, more preferably 0.0001% to 0.5% by mass, and still more preferably 0.0003% to 0.2% by mass with respect to the total mass of the treatment liquid.

From the viewpoint that the effect of the present invention is more excellent, the content of the heterocyclic compound is preferably 0.1% to 8.0% by mass, more preferably 0.15% to 7.0% by mass, and still more preferably 0.3% to 5.0% by mass with respect to the total mass of components in the treatment liquid excluding a solvent.

### [Water]

The treatment liquid contains water.

The type of water used in the treatment liquid may be any type of water as long as it does not adversely affect the semiconductor substrate; and distilled water, deionized (DI) water, or pure water (ultrapure water) can be used. The pure water (ultrapure water) is preferable from the viewpoint that it contains almost no impurities and has less influence on a semiconductor substrate in a step of manufacturing the semiconductor substrate.

A content of water may be a remainder of components which can be contained in the treatment liquid.

The content of water is preferably 80% by mass or more, more preferably 85% by mass or more, and still more preferably 90% by mass or more with respect to the total mass of the treatment liquid. From the viewpoint that the effect of the present invention is more excellent, the upper limit thereof is preferably 99.999% by mass or less, more preferably 99.99% by mass or less, and still more preferably 99.97% by mass or less.

### [Other Components]

The treatment liquid may contain at least one component selected from the group consisting of a quaternary ammonium compound having a hydroxyl group, other amine compounds, a chelating agent, a specific acidic compound, a pH adjuster, a surfactant, an organic solvent, a polymer, a polyhydroxy compound having a molecular weight of 500 or more, and an oxidant, in addition to the above-described compounds.

Hereinafter, other components will be described.

### <Quaternary Ammonium Compound Having Hydroxyl Group>

The treatment liquid may contain a quaternary ammonium compound having a hydroxyl group.

Examples of the above-described quaternary ammonium compound having a hydroxyl group include tris(2-hydroxyethyl)methylammonium hydroxide (THEMAH), 2-hydroxyethyltrimethylammonium hydroxide (Choline hydroxide), dimethylbis(2-hydroxyethyl)ammonium hydroxide, bis(2-hydroxyethyl)dimethylammonium hydroxide, tri(2-hydroxyethyl)methylammonium hydroxide, and tetra(2-hydroxyethyl)ammonium hydroxide.

In a case of containing the quaternary ammonium compound having a hydroxyl group, from the viewpoint that the effect of the present invention is more excellent, a content thereof is preferably 0.0001% to 0.5% by mass, and more preferably 0.0005% to 0.1% by mass with respect to the total mass of the treatment liquid.

From the viewpoint that the effect of the present invention is more excellent, it is also preferable that the treatment liquid does not substantially contain the quaternary ammonium compound having a hydroxyl group. The expression “does not substantially contain the quaternary ammonium compound having a hydroxyl group” means that the content of the quaternary ammonium compound having a hydroxyl group is 1% by mass or less, preferably 0.1% by mass or less, and more preferably 0.01% by mass or less with respect to the content of the quaternary ammonium compound. The lower limit thereof is not particularly limited, and is 0% by mass.

### <Other Amine Compounds>

The treatment liquid may contain other amine compounds different from each of the above-described components (the quaternary ammonium compound, the tertiary alkylamine compound, and the heterocyclic compound) and an organic acid described later.

Examples of other amine compounds include a primary amine compound and a secondary amine compound. The primary amine compound and the secondary amine compound are each a compound having a primary amino group (—NH₂) or a secondary amino group (>NH) in the molecule. Furthermore, in a case where the compound has amino groups of different classes, it is classified into the highest amine compound.

The other amine compounds may have a substituent. Examples of the substituent other than the amino group include a hydroxyl group.

The other amine compounds may have an ether bond in the molecule.

The number of primary amino groups and secondary amino groups in the other amine compounds is not particularly limited, but is preferably 1 to 6, more preferably 2 to 4, and still more preferably 2 or 3.

Examples of the other amine compounds include ethylenediamine (EDA), 1,3-propanediamine (PDA), 1,2-propanediamine, 1,3-butanediamine, 1,4-butanediamine, diethylenetriamine (DETA), triethylenetetramine (TETA), and tetraethylenepentamine.

In addition, examples thereof include an amine compound having a hydroxyl group, such as monoethanolamine (MEA), uracil, 2-amino-2-methyl-1-propanol (AMP), N-methyl-2-amino-2-methyl-propanol (MAMP), 2-(2-aminoethylamino)ethanol (AAE), 3-amino-1-propanol, 1-amino-2-propanol, N,N′-bis(2-hydroxyethyl)ethylenediamine, trishydroxymethylaminomethane, diethylene glycolamine (DEGA), 2-(aminoethoxy)ethanol (AEE), N-methylethanolamine, 2-(ethylamino)ethanol, 2-[(hydroxymethyl)amino]ethanol, 2-(propylamino)ethanol, diethanolamine, N-butylethanolamine, and N-cyclohexylethanolamine.

The other amine compounds may be used alone, or two or more types thereof may be used in combination.

A content of the other amine compounds is preferably 0.00001% to 10.0% by mass, and more preferably 0.0001% to 0.1% by mass with respect to the total mass of the treatment liquid.

The content of the other amine compounds is preferably 0.01% to 50.0% by mass, and more preferably 0.1% to 30.0% by mass with respect to the total mass of components in the treatment liquid excluding a solvent.

### <Chelating Agent>

The treatment liquid may contain a chelating agent. The chelating agent is a compound different from each of the above-described components (the quaternary ammonium compound, the tertiary alkylamine compound, the other amine compounds, and the heterocyclic compound).

The chelating agent is a compound having a functional group (coordinating group) which can function as a ligand.

Examples of the coordinating group included in the chelating agent include a carboxy group, a phosphonate group, and a sulfo group, and a carboxy group or a phosphonate group is preferable.

Examples of the chelating agent include an organic chelating agent and an inorganic chelating agent.

The organic chelating agent is a chelating agent containing an organic compound, and examples thereof include a carboxylic acid-based chelating agent having a carboxy group as a coordinating group and a phosphonic acid-based chelating agent having a phosphonic acid group as a coordinating group.

Examples of the inorganic chelating agent include a fused phosphoric acid and a salt thereof.

As the chelating agent, the organic chelating agent is preferable.

The chelating agent preferably has a low molecular weight. Specifically, the molecular weight of the chelating agent is preferably 600 or less, more preferably 450 or less, and still more preferably 300 or less. The lower limit thereof is preferably 50 or more and more preferably 100 or more.

The number of carbon atoms in the chelating agent is preferably 1 to 15 and more preferably 2 to 15.

### (Carboxylic Acid-Based Chelating Agent)

Examples of the carboxylic acid-based chelating agent include a polycarboxylic acid and a hydroxycarboxylic acid.

The polycarboxylic acid is a compound having two or more carboxy groups in the molecule and not having an amino group in the molecule.

Examples of the polycarboxylic acid include succinic acid, citric acid, malonic acid, maleic acid, malic acid, tartaric acid, oxalic acid, glutaric acid, adipic acid, pimelic acid, and sebacic acid.

Examples of the hydroxycarboxylic acid include gluconic acid, heptonic acid, glycolic acid, and lactic acid.

Among these, as the carboxylic acid-based chelating agent, a polycarboxylic acid is preferable; succinic acid, citric acid, malonic acid, or oxalic acid is more preferable; and succinic acid is still more preferable.

### (Phosphonic Acid-Based Chelating Agent)

Examples of the phosphonic acid-based chelating agent include 1-hydroxyethyldiene-1,1′-diphosphonic acid (etidronic acid; HEDP), ethylidenediphosphonic acid, 1-hydroxypropyridene-1,1′-diphosphonic acid, 1-hydroxybutylidene-1,1′-diphosphonic acid, ethylaminobis(methylenephosphonic acid), dodecylaminobis(methylenephosphonic acid), and nitrilotris(methylenephosphonic acid) (NTPO).

As the phosphonic acid-based chelating agent other than those described above, compounds described in paragraphs [0026] to [0036] of WO2018/020878A and compounds ((co)polymers) described in paragraphs [0031] to [0046] of WO2018/030006A can be used, the contents of which are incorporated herein by reference.

Among these, as the phosphonic acid-based chelating agent, HEDP or NTPO is preferable.

The chelating agent may be used alone, or two or more types thereof may be used in combination.

A content of the chelating agent is preferably 0.0001% to 1.0% by mass, more preferably 0.0005% to 0.1% by mass, and still more preferably 0.001% to 0.05% by mass with respect to the total mass of the treatment liquid.

The content of the chelating agent is preferably 0.1% to 30.0% by mass and more preferably 1.0% to 15.0% by mass with respect to the total mass of components in the treatment liquid excluding a solvent.

### <Specific Acidic Compound>

The treatment liquid may contain a specific acidic compound.

The specific acidic compound is a compound different from the above-described compounds which can be contained in the treatment liquid (the quaternary ammonium compound, the tertiary alkylamine compound, the other amine compounds, the heterocyclic compound, and the chelating agent).

The specific acidic compound is an acidic compound having a sulfo group, and examples thereof include sulfuric acid and sulfonic acid.

Specific examples of the sulfonic acid include p-toluenesulfonic acid, naphthalenesulfonic acid, camphor sulfonic acid, benzenesulfonic acid, methanesulfonic acid, ethanesulfonic acid, methanedisulfonic acid, 1,2-ethanesulfonic acid, and 1,3-benzenedisulfonic acid.

As the specific acidic compound, a salt of the above-described acidic compound having a sulfo group may be used.

The specific acidic compound may be used alone, or two or more types thereof may be used in combination.

A content of the specific acidic compound is preferably 0.0001% to 1.0% by mass, more preferably 0.0005% to 0.1% by mass, and still more preferably 0.001% to 0.05% by mass with respect to the total mass of the treatment liquid.

The content of the specific acidic compound is preferably 0.1% to 30.0% by mass, and more preferably 1.0% to 15.0% by mass with respect to the total mass of components in the treatment liquid excluding a solvent.

### <pH Adjuster>

The treatment liquid may include a pH adjuster to adjust and maintain the pH of the treatment liquid.

The pH adjuster is a basic compound and an acidic compound, which are different from the above-described compounds which can be contained in the treatment liquid. However, it is permissible to adjust the pH of the treatment liquid by adjusting the adding amount of each of the components contained in the treatment liquid.

The basic compound is a compound which exhibits basicity (pH of more than 7.0) in an aqueous solution, and examples thereof include a basic inorganic compound.

Examples of the basic inorganic compound include alkali metal hydroxides such as sodium hydroxide and potassium hydroxide, and alkaline earth metal hydroxides.

The acidic compound as the pH adjuster is a compound which exhibits acidity (pH of less than 7.0) in an aqueous solution, and examples thereof include an acidic inorganic compound.

Examples of the acidic inorganic compound include hydrochloric acid, nitric acid, nitrous acid, sulfurous acid, phosphoric acid, boric acid, and hexafluorophosphoric acid.

As the acidic compound as the pH adjuster, a salt of the acidic compound may be used as long as it is an acid or an acid ion (anion) in an aqueous solution.

The pH adjuster may be used alone, or two or more types thereof may be used in combination.

A content of the pH adjuster can be selected depending on the type and amount of other components and the target pH of the treatment liquid. For example, the content of the pH adjuster is preferably 0.0001% to 10% by mass, more preferably 0.001% to 8% by mass, and still more preferably 0.001% to 0.1% by mass with respect to the total mass of the treatment liquid.

The content of the pH adjuster is preferably 0.01% to 80% by mass, more preferably 0.1% to 60% by mass, and still more preferably 0.1% to 30% by mass with respect to the total mass of components in the treatment liquid excluding a solvent.

### <Abrasive Particles>

It is preferable that the treatment liquid does not substantially contain abrasive particles.

The abrasive particles mean particles which are contained in a polishing liquid used for performing a polishing treatment on a semiconductor substrate and have an average primary particle diameter of 5 nm or more.

Examples of the above-described abrasive particles include inorganic solids such as silica (including colloidal silica and fumed silica), alumina, zirconia, ceria, titania, germania, manganese oxide, and silicon carbide; and organic solids such as polystyrene, a polyacrylic resin, and polyvinyl chloride.

The expression “does not substantially contain the abrasive particles” means that the content of the abrasive particles is less than 0.1% by mass, preferably 0.01% by mass or less, and more preferably 0.001% by mass or less with respect to the total mass of the treatment liquid. The lower limit thereof is not particularly limited, and is 0% by mass.

The content of the abrasive particles can be measured using a commercially available measuring device in a light scattering type liquid particle measuring method using a laser as a light source.

In addition, an average primary particle diameter of particles such as abrasive particles is determined by measuring particle diameters (equivalent circle diameter) of 1,000 primary particles randomly selected from an image obtained using a transmission electron microscope TEM2010 (acceleration voltage: 200 kV) manufactured by JEOL Ltd., and calculating an arithmetic mean thereof. The equivalent circle diameter is a diameter of a virtual perfect circle assumed to have the same projected area as the projected area of particles observed.

Examples of a method for removing the abrasive particles from the treatment liquid include a purification treatment such as filtering.

### <Surfactant>

The surfactant is not particularly limited as long as it is a compound having a hydrophilic group and a hydrophobic group (lipophilic group) in one molecule; and examples thereof include a nonionic surfactant and an anionic surfactant.

In many cases, the surfactant has at least one hydrophobic group selected from the group consisting of an aliphatic hydrocarbon group, an aromatic hydrocarbon group, and a group obtained by combining these groups.

The number of carbon atoms in the surfactant is preferably 16 to 100.

Examples of the nonionic surfactant include an ester-type nonionic surfactant, an ether-type nonionic surfactant, and an ester-ether-type nonionic surfactant; and an ether-type nonionic surfactant is preferable.

As the nonionic surfactant, for example, compounds exemplified in paragraph [0126] of WO2022/044893A can be used, the contents of which are incorporated herein by reference.

As the anionic surfactant, for example, compounds exemplified in paragraphs [0118] and [0122] of WO2022/044893A can be used, the contents of which are incorporated herein by reference.

The surfactant may be used alone, or two or more types thereof may be used in combination.

From the viewpoint of excellent performance of the treatment liquid, a content of the surfactant is preferably 0.00001% to 8.0% by mass, more preferably 0.0001% to 5.0% by mass, and still more preferably 0.005% to 3.0% by mass with respect to the total mass of the treatment liquid.

From the viewpoint of excellent performance of the treatment liquid, the content of the surfactant is preferably 0.01% to 50.0% by mass, more preferably 0.1% to 45.0% by mass, and still more preferably 1.0% to 20.0% by mass with respect to the total mass of components in the treatment liquid excluding a solvent.

### <Organic Solvent>

Examples of the organic solvent include known organic solvents, for example, an alcohol-based solvent, a glycol-based solvent, a glycol ether-based solvent, and a ketone-based solvent.

It is preferable that the organic solvent is mixed with water at an optional ratio.

As the organic solvent, for example, compounds exemplified in paragraphs [0135] to [0140] of WO2022/044893A can be used, the contents of which are incorporated herein by reference.

### <Polymer>

As the polymer, water-soluble polymers described in paragraphs [0043] to [0047] of JP2016-171294A can be used, the contents of which are incorporated herein by reference.

### <Polyhydroxy Compound Having Molecular Weight of 500 or More>

The polyhydroxy compound having a molecular weight of 500 or more is a compound different from the above-described compounds which can be contained in the treatment liquid.

The above-described polyhydroxy compound is an organic compound having 2 or more (for example, 2 to 200) alcoholic hydroxyl groups in one molecule.

A molecular weight (in a case of having a molecular weight distribution, a weight-average molecular weight) of the above-described polyhydroxy compound is 500 or more, preferably 500 to 100,000 and more preferably 500 to 3,000.

As the polyhydroxy compound, compounds exemplified in paragraphs [0101] and [0102] of WO2022/014287A can be used, the contents of which are incorporated herein by reference.

### [Physical Properties of Treatment Liquid]

<pH>

The treatment liquid may be either alkaline or acidic.

From the viewpoint that the effect of the present invention is more excellent, the pH of the treatment liquid is preferably 8.0 to 14.0, more preferably 10.0 to 14.0, and still more preferably 10.5 to 13.5.

The pH of the treatment liquid can be measured by a method based on JIS Z 8802-1984 using a known pH meter. A measurement temperature of the pH is 25° C.

### <Metal Content>

A content (measured as ion concentration) of all metals (for example, metal elements of Fe, Co, Na, Cu, Mg, Mn, Li, Al, Cr, Ni, Zn, Sn, and Ag) contained as impurities in the treatment liquid is preferably 5 ppm by mass or less, and more preferably 1 ppm by mass or less. It is assumed that, in manufacturing of a cutting-edge semiconductor element, a treatment liquid having even higher purity is required, and thus the content of the metal is more preferably a value lower than 1 mass ppm, that is, lower than a value of mass ppb order, particularly preferably 100 mass ppb or less, and most preferably less than 10 mass ppb. The lower limit thereof is preferably 0.

Examples of a method for reducing the metal content include performing a purifying treatment such as distillation and filtration using an ion exchange resin or a filter at a stage of raw materials used in the production of the treatment liquid or a stage after the production of the treatment liquid.

Other examples of the method for reducing the metal content include using a container with less elution of impurities, which will be described later, as a container that accommodates the raw material or the produced treatment liquid. In addition, other examples thereof include lining an interior wall of the pipe with a fluororesin to prevent the elution of metal components from a pipe or the like during the production of the treatment liquid.

### <Coarse Particles>

The treatment liquid may contain coarse particles, but it is preferable that a content thereof is preferably low.

The coarse particles mean particles having a diameter (particle size) of 1 μm or more, in a case where a shape of the particles is regarded as a sphere.

The coarse particles contained in the treatment liquid correspond to, for example, particles such as rubbish, dust, organic solid, and inorganic solid, which are contained as impurities in raw materials, and particles such as rubbish, dust, organic solid, and inorganic solid, which are brought in as contaminants during the preparation of the treatment liquid, in which those particles are finally present as particles without being dissolved in the treatment liquid.

The content of the coarse particles in the treatment liquid, in terms of content of particles having a particle size of 1 μm or more, is preferably 100 or less and more preferably 50 or less per 1 mL of the treatment liquid. The lower limit thereof is preferably 0 or more, and more preferably 0.01 or more per milliliter of the treatment liquid.

The content of the coarse particles present in the treatment liquid can be measured in a liquid phase by using a commercially available measuring device in a light scattering type liquid particle measuring method using a laser as a light source.

Examples of a method for removing the coarse particles include a purification treatment such as filtering, which will be described later.

### [Production Method of Treatment Liquid]

The treatment liquid can be produced by a known method. Hereinafter, a production method of the treatment liquid will be described in detail.

### [Liquid Preparation Step]

The treatment liquid can be produced, for example, by mixing the above-described components.

Examples of the method for preparing the treatment liquid include a method in which the quaternary ammonium compound having no hydroxyl group, the tertiary alkylamine compound, the heterocyclic compound, and, as necessary, an optional component are sequentially charged into a container containing purified pure water, the mixture is stirred and mixed, and a pH adjuster is added as necessary to adjust the pH of the mixed solution, thereby preparing the treatment liquid. In addition, in a case where the respective components are charged into the container, the respective components may be charged at once, or may be charged in a divided manner a plurality of times.

As a stirring device and a stirring method used for preparing the treatment liquid, a known device may be used as a stirrer or a disperser. Examples of a stirrer include an industrial mixer, a portable stirrer, a mechanical stirrer, and a magnetic stirrer. Examples of the disperser include an industrial disperser, a homogenizer, an ultrasonic disperser, and a beads mill.

The mixing of the respective components in the step of preparing the treatment liquid, a refining treatment described later, and storage of the produced treatment liquid are preferably performed at 40° C. or lower, and more preferably performed at 30° C. or lower. The lower limit thereof is preferably 5° C. or higher and more preferably 10° C. or higher. By preparing, treating, and/or storing the treatment liquid in the above-described temperature range, stable performance can be maintained for a long period of time.

### <Purification>

It is preferable to subject any one or more of the raw materials for preparing the treatment liquid to a purification treatment in advance. Examples of the purification treatment include known methods such as distillation, ion exchange, and filtration (filtering).

Regarding a degree of purification, it is preferable to carry out the purification treatment until the purity of the raw material is 99% by mass or more, and it is more preferable to carry out the purification treatment until the purity of the stock solution is 99.9% by mass or more. The upper limit thereof is preferably 99.9999% by mass or less.

Examples of a method of the purification treatment include a method of passing the raw material through an ion exchange resin, a reverse osmosis membrane (RO membrane), or the like, reprecipitation, distillation of a raw material, and filtering.

The purification treatment may be carried out by combining a plurality of the above-described purification methods. For example, the raw materials are subjected to primary purification by passing through an RO membrane, and then subjected to secondary purification by passing through a purification device consisting of a cation-exchange resin, an anion-exchange resin, or a mixed-bed type ion exchange resin.

In addition, the purification treatment may be performed a plurality of times.

The filter which is used for filtering is not particularly limited as long as it has been used in application for filtering and the like in the related art. Examples thereof include filters formed of fluororesins such as polytetrafluoroethylene (PTFE) and tetrafluoroethylene perfluoroalkyl vinyl ether copolymer (PFA), polyamide-based resins such as nylon, polyarylsulfone (PAS), polyolefin resins (including those with a high density and a ultra-high molecular weight) such as polyethylene and polypropylene (PP), or the like. Among these materials, a material selected from the group consisting of polyethylene, polypropylene (including a high-density polypropylene), a fluororesin (including PTFE and PFA), and a polyamide-based resin (including nylon) is preferable; and a filter of the fluororesin is more preferable. By carrying out filtering of the raw materials using a filter formed of these materials, high-polarity foreign matters which are likely to cause defects can be more effectively removed.

### <Container>

The treatment liquid (including an aspect of a diluted treatment liquid described later) can be added in any container to be stored and transported as long as problems such as corrosiveness do not arise.

In application for a semiconductor, the container is preferably a container which has a high degree of cleanliness inside the container and in which the elution of impurities from an interior wall of an accommodating portion of the container into the each liquid is suppressed. Examples of such a container include various containers commercially available as a container for a semiconductor treatment liquid, such as “CLEAN BOTTLE” series manufactured by AICELLO MILIM CHEMICAL Co., Ltd. and “PURE BOTTLE” manufactured by Kodama Plastics Co., Ltd., but the container is not limited thereto.

In addition, as the container, containers exemplified in paragraphs [0121] to [0124] of WO2022/004217A can also be used, the contents of which are incorporated herein by reference.

The inside of these containers is preferably cleaned before filling the treatment liquid. With regard to a liquid used for the cleaning, the amount of metal impurities in the liquid is preferably reduced. The treatment liquid may be bottled in a container such as a gallon bottle and a coated bottle after the production, and then may be transported and stored.

In order to prevent changes in the components of the treatment liquid during the storage, the inside of the container may be purged with an inert gas (such as nitrogen and argon) having a purity of 99.99995% by volume or more. In particular, a gas with a low moisture content is preferable. In addition, during the transportation and the storage, the temperature may be normal temperature or may be controlled in a range of −20° C. to 20° C. to prevent deterioration.

### <Clean Room>

It is preferable that handlings including production of the treatment liquid, opening and cleaning of the container, and filling of the treatment liquid, treatment analysis, and measurements are all performed in a clean room. It is preferable that the clean room meets the 14644-1 clean room standard. It is preferable that the clean room satisfies any one of International Organization for Standardization (ISO) Class 1, ISO Class 2, ISO Class 3, or ISO Class 4, it is more preferable that the clean room satisfies ISO Class 1 or ISO Class 2, and it is still more preferable that the clean room satisfies ISO Class 1.

### [Dilution Step]

The above-described treatment liquid may be used for treating an object to be treated, as a diluted treatment liquid after undergoing a dilution step of diluting the treatment liquid using a diluent such as water.

The diluted treatment liquid is also an aspect of the treatment liquid according to the embodiment of the present invention as long as it satisfies the requirements of the present invention.

It is preferable to subject the diluent which is used in the dilution step to a purification treatment in advance. In addition, it is more preferable that the diluted treatment liquid obtained in the dilution step is subjected to a purification treatment.

Examples of the purification treatment include the ion component reducing treatment using the ion exchange resin, the RO membrane, or the like, and the foreign matter removal using filtering, which are described as the purification treatment for the treatment liquid above, and it is preferable to carry out any one of these treatments.

A dilution rate of the treatment liquid in the dilution step may be appropriately adjusted depending on the type and content of each component and the object to be treated, but the ratio (dilution rate) of the diluted treatment liquid to the treatment liquid before the dilution is preferably 10 to 10,000 times, more preferably 20 to 3,000 times, and still more preferably 50 to 1,000 times in terms of mass ratio or volume ratio (volume ratio at 23° C.).

In addition, from the viewpoint of more excellent defect removability, the treatment liquid is preferably diluted with water (preferably, ultrapure water).

A change in pH before and after the dilution (a difference between the pH of the treatment liquid before the dilution and the pH of the diluted treatment liquid) is preferably 2.0 or less, more preferably 1.8 or less, and still more preferably 1.5 or less.

It is preferable that the pH of the treatment liquid before the dilution and the pH of the diluted treatment liquid are each in the above-described suitable aspect.

A specific method for the dilution step of diluting the treatment liquid may be performed according to the step of preparing the treatment liquid described above. A stirring device and a stirring method used in the dilution step may also be performed using the known stirring device described in the step of preparing the treatment liquid above.

### [Use Application]

The treatment liquid is used for an object to be treated (particularly, a semiconductor substrate) which has been subjected to a chemical mechanical polishing (CMP) treatment, and it is more preferably used in a cleaning step of the object to be treated which has been subjected to a CMP treatment.

The treatment liquid may be used in other steps after the CMP treatment and before the cleaning step, and for example, may be used in a step of cleaning the object to be treated after the CMP treatment through a pad cleaning treatment step. In addition, the treatment liquid may be used for cleaning a semiconductor substrate in any step in the manufacturing process of the semiconductor substrate.

As described above, in a case where the treatment liquid is used, the treatment liquid may be used as a diluted treatment liquid obtained by diluting the treatment liquid.

Among these, the treatment liquid is preferably used for an object to be treated containing a metal, which has been subjected to a CMP treatment.

Hereinafter, the object to be treated of the treatment liquid according to the embodiment of the present invention will be described in detail.

### [Object to be Treated]

Examples of the object to be treated include an object to be treated containing a metal. Among these, a semiconductor substrate containing a metal is preferable.

The above-described metal may be located on any of a front surface, a back surface, side surfaces, the inside of the groove, or the like of the semiconductor substrate. In addition, in a case where the semiconductor substrate contains a metal, the metal includes not only a case in which the metal is directly present on the surface of the semiconductor substrate, but also a case in which the metal is present on the semiconductor substrate through another layer.

Examples of the above-described metal include at least one metal M selected from the group consisting of copper (Cu), cobalt (Co), ruthenium (Ru), aluminum (Al), tungsten (W), titanium (Ti), tantalum (Ta), chromium (Cr), hafnium (Hf), osmium (Os), platinum (Pt), nickel (Ni), manganese (Mn), iron (Fe), zirconium (Zr), molybdenum (Mo), palladium (Pd), lanthanum (La), niobium (Nb), and iridium (Ir); and at least one metal selected from the group consisting of Cu, Co, Ru, Mo, and W is preferable, at least one metal selected from the group consisting of Cu and Co is more preferable, and Cu is still more preferable. That is, the object to be treated is preferably an object to be treated containing Cu.

The metal is preferably present as a metal layer containing a metal. Examples of a form of the metal contained in the metal layer include a simple substance of the metal M and an alloy containing the metal M.

Among these, the object to be treated preferably has a metal layer containing the metal M, more preferably has a metal layer containing Cu, Co, Ru, Mo, or W, still more preferably has a metal layer containing Cu or Co, and particularly preferably has a metal layer containing Cu.

Examples of a metal layer containing Cu (Cu-containing film) include a wire film consisting of only metal copper (copper wire film), and a wire film made of an alloy consisting of metal copper and another metal (a copper alloy wire film).

Examples of a copper alloy wire film include a wire film made of an alloy consisting of at least one metal selected from the group consisting of Al, Ti, Cr, Mn, Ta, Nb, and W, and Cu. More specific examples thereof include a copper-aluminum alloy wire film (CuAl alloy wire film), a copper-titanium alloy wire film (CuTi alloy wire film), a copper-chromium alloy wire film (CuCr alloy wire film), a copper-manganese alloy wire film (CuMn alloy wire film), a copper-tantalum alloy wire film (CuTa alloy wire film), a copper-niobium alloy wire film (CuNb alloy wire film), and a copper-tungsten alloy wire film (CuW alloy wire film).

Examples of a metal layer containing Co (Co-containing film) include a metal film consisting of only metal cobalt (cobalt metal film), and a metal film made of an alloy consisting of metal cobalt and another metal (cobalt alloy metal film).

Examples of a cobalt alloy metal film include a metal film made of an alloy consisting of at least one metal selected from the group consisting of Ti, Cr, Fe, Ni, Mo, Pd, Ta, Nb, and W, and Co. More specific examples thereof include a cobalt-titanium alloy metal film (a CoTi alloy metal film), a cobalt-chromium alloy metal film (a CoCr alloy metal film), a cobalt-iron alloy metal film (a CoFe alloy metal film), a cobalt-nickel alloy metal film (a CoNi alloy metal film), a cobalt-molybdenum alloy metal film (a CoMo alloy metal film), a cobalt-palladium alloy metal film (a CoPd alloy metal film), a cobalt-tantalum alloy metal film (a CoTa alloy metal film), a cobalt-niobium alloy metal film (a CoNb alloy metal film), and a cobalt-tungsten alloy metal film (a CoW alloy metal film).

The object to be treated with the treatment liquid may have, for example, a semiconductor substrate, an insulating film, and a barrier metal, in addition to the above-described metal wire film.

Examples of the wafer constituting the semiconductor substrate include a wafer consisting of a silicon-based material, such as a silicon (Si) wafer, a silicon carbide (SiC) wafer, and a silicon-including resin-based wafer (glass epoxy wafer), a gallium phosphorus (GaP) wafer, a gallium arsenic (GaAs) wafer, and an indium phosphorus (InP) wafer.

Examples of the silicon wafer include an n-type silicon wafer in which a silicon wafer is doped with a pentavalent atom (for example, phosphorus (P), arsenic (As), antimony (Sb), or the like) and a p-type silicon wafer in which a silicon wafer is doped with a trivalent atom (for example, boron (B), gallium (Ga), or the like). Examples of the silicon of the silicon wafer include amorphous silicon, single crystal silicon, polycrystalline silicon, and polysilicon.

Among these, a wafer consisting of a silicon-based material, such as a silicon wafer, a silicon carbide wafer, and a resin-based wafer (a glass epoxy wafer) including silicon, is preferable.

Examples of the insulating film include a silicon oxide film (for example, a silicon dioxide (SiO₂) film, a tetraethyl orthosilicate (Si(OC₂H₅)₄) film (a TEOS film), a silicon nitride film (for example, silicon nitride (Si₃N₄), and silicon nitride carbide (SiNC)), and a low-dielectric-constant (Low-k) film (for example, a carbon-doped silicon oxide (SiOC) film, a black diamond (BD) film, and a silicon carbide (SiC) film); and a low-dielectric-constant (Low-k) film is preferable.

Examples of the barrier metal include tantalum (Ta), tantalum nitride (TaN), titanium nitride (TiN), tungsten (W), tungsten alloy (tungsten-titanium (WTi) alloy, tungsten-cobalt (WCo) alloy, and the like), cobalt (Co), cobalt alloy, ruthenium (Ru), and ruthenium alloy.

A method of forming the insulating film, the copper-containing film, and the cobalt-containing film described above on the wafer constituting the semiconductor substrate is not particularly limited as long as it is a method generally carried out in this field.

Examples of the method of forming the insulating film include a method in which the wafer constituting the semiconductor substrate is subjected to a heat treatment in the presence of oxygen gas to form a silicon oxide film, and then a gas of silane and ammonia is introduced thereto to form a silicon nitride film by a chemical vapor deposition (CVD) method.

Examples of the method of forming the copper-containing film and the cobalt-containing film include a method of forming a circuit on the wafer having the above-described insulating film by a known method such as a resist, and then forming the metal layer by a method such as plating, a physical vapor deposition (PVD) method, and a CVD method. The object to be treated may have a layer for forming the copper-containing film or the cobalt-containing film on the above-described insulating layer.

### <CMP Treatment>

The treatment liquid is used for the object to be treated which has been subjected to a CMP treatment. The object to be treated is preferably an object to be treated containing a metal, which has been subjected to a CMP treatment, and more preferably a semiconductor substrate containing a metal, which has been subjected to a CMP treatment.

The CMP treatment is a treatment in which a surface of the substrate having a layer selected from the metal wire film, the barrier metal, and the insulating film is flattened by a combined action of a chemical action and a mechanical polishing using a polishing slurry containing abrasive particles (abrasive grains).

A surface of the object to be treated which has been subjected to the CMP treatment may have residues such as abrasive grains (for example, silica and alumina) used in the CMP treatment, a polished metal wire film, and/or metal impurities (metal residue) derived from the barrier metal. In addition, an organic substance derived from a CMP treatment liquid used in the CMP treatment may remain as the residues. For example, since these residues may cause a short-circuit between wiring lines and deteriorate electrical characteristics of the semiconductor substrate, the semiconductor substrate which has been subjected to the CMP treatment is subjected to a cleaning treatment for removing these residues from the surface.

Specific examples of the object to be treated, which has been subjected to the CMP treatment, include substrates which have been subjected to the CMP treatment, described in Journal of the Japan Society for Precision Engineering, Vol. 84, No. 3, 2018, but the present invention is not limited thereto.

<Object to be Treated which has been Subjected to Pad Cleaning Treatment>

The surface of the object to be treated may be subjected to a pad cleaning treatment after the CMP treatment.

The pad cleaning treatment is a treatment of reducing residues present on the surface of the portion to be treated using a pad. Specifically, the surface of the object to be treated, which has been subjected to the CMP treatment, is brought into contact with the pad, and the object to be treated and the pad are relatively slid while supplying a composition for pad cleaning to a contact portion. As a result, the residues on the surface of the object to be treated are removed by a frictional force of the pad and the chemical action of the composition for pad cleaning.

The above-described pad is not particularly limited, and can be appropriately selected depending on the type of the object to be treated, the type of residues to be removed, and the device to be used. As the pad, a polishing pad used in the CMP treatment may be used, or a buff pad such as a foamed polyurethane-based buff pad, a nonwoven fabric, a suede-based buff pad, and a sponge may be used. The pad cleaning treatment using the pad includes a treatment called buff cleaning or buff polishing.

As the above-described composition for pad cleaning, a known cleaning composition can be used depending on the type of the object to be treated and the type and amount of the residues to be removed. Examples of components contained in the composition for pad cleaning include a water-soluble polymer such as polyvinyl alcohol, a dispersion medium such as water, and an acid such as nitric acid. In addition, the composition for pad cleaning does not contain abrasive particles.

The device and conditions used in the pad cleaning treatment can be appropriately selected from known devices and conditions depending on the type of the treatment object and the type and amount of the residues to be removed. For example, a treatment method described in paragraphs [0085] to [0088] of WO2017/169539A can be used, the contents of which are incorporated herein by reference.

In addition, as one embodiment of the pad cleaning treatment, it is also preferable to perform a pad cleaning treatment on the object to be treated, using the treatment liquid according to the embodiment of the present invention as the composition for pad cleaning.

The treatment liquid to be subjected to the pad cleaning treatment may be a diluted treatment liquid.

The pad cleaning treatment may be performed only once or may be performed twice or more. For example, after the CMP treatment, a pad cleaning treatment using a polishing pad and a pad cleaning treatment using a buff pad may be performed.

### [Cleaning Method of Object to be Treated]

The cleaning method of the object to be treated includes a cleaning step of cleaning the object to be treated, which has been subjected to the CMP treatment, using the above-described treatment liquid.

The treatment liquid to be used in the above-described cleaning step may be a diluted treatment liquid.

As the cleaning step of cleaning the object to be treated using the treatment liquid, a known cleaning method which is performed on the object to be treated which has been subjected to the CMP treatment can be used.

Examples of the cleaning method include a method of bringing the object to be treated into contact with the treatment liquid. The above-described contact method is not particularly limited; and examples thereof include a method of immersing the object to be treated in the treatment liquid contained in a tank, a method of spraying the treatment liquid onto the object to be treated, a method of flowing the treatment liquid onto the object to be treated, and a combination thereof. The above-described method may be appropriately selected depending on the purpose.

In addition, the above-described method may appropriately adopt a method usually performed in the field. For example, scrub cleaning in which a cleaning member such as a brush is physically brought into contact with a surface of the object to be treated while supplying the treatment liquid to remove residues and the like, spinning (dropping) cleaning in which the treatment liquid is dropped while rotating the object to be treated, or the like may be used. From the viewpoint that impurities remaining on a surface of the object to be treated can be further reduced, it is preferable that the object to be treated immersed in the treatment liquid is subjected to an ultrasonic treatment.

The above-described cleaning step may be carried out once or twice or more. In a case of carrying out the cleaning twice or more, the same method may be repeated or different methods may be combined.

The cleaning method of the object to be treated may be a single-wafer method or a batch method. The single-wafer method is a method of treating one object to be treated at a time; and the batch method is a method of treating a plurality of objects to be treated at the same time.

A temperature of the treatment liquid in the cleaning step is not particularly limited, but from the viewpoint of defect removability, it is preferably 10° C. to 60° C., more preferably 15° C. to 50° C., and still more preferably 15° C. to 40° C.

It is preferable that a pH of the treatment liquid and a pH of the diluted treatment liquid are each in the above-described suitable aspect of pH.

A cleaning time in the cleaning step may be appropriately changed depending on the type, content, and the like of the components which can be contained in the treatment liquid, but is preferably 10 to 120 seconds, more preferably 20 to 90 seconds, and still more preferably 30 to 60 seconds.

A supply amount (supply rate) of the treatment liquid in the cleaning step is preferably 50 to 5,000 mL/min, and more preferably 500 to 2,000 mL/min.

In the cleaning step, a mechanical stirring method may be used in order to further improve the cleaning ability of the treatment liquid. Examples of the mechanical stirring method include a method of circulating the treatment liquid on the object to be treated, a method of flowing or spraying the treatment liquid on the object to be treated, and a method of stirring the treatment liquid with ultrasonic wave or megasonic wave.

After the cleaning step, a step of bringing the object to be treated into contact with a rinsing liquid (hereinafter, also referred to as “rinsing step”) may be performed. By performing the rinsing step, the object to be treated, obtained in the cleaning step, is washed with a rinsing liquid, and the residues can be efficiently removed.

The rinsing step is preferably a step which is performed continuously subsequently after the cleaning step of the object to be treated, which is performed continuously after the cleaning step of the object to be treated. The rinsing step may be performed using the above-described mechanical stirring method.

Examples of the rinsing liquid include water (preferably, DI water), methanol, ethanol, isopropyl alcohol (IPA), N-methylpyrrolidinone, γ-butyrolactone, dimethyl sulfoxide, ethyl lactate, and propylene glycol monomethyl ether acetate. In addition, an aqueous rinsing liquid having a pH of more than 8.0 (aqueous ammonium hydroxide which has been diluted, or the like) may be used.

As the method in which the rinsing liquid is brought into contact with the object to be treated, the method in which the treatment liquid is brought into contact with the object to be treated can be similarly applied.

A contact time between the object to be treated and the rinsing liquid can be appropriately changed depending on the type and content of each component contained in the treatment liquid, and the use target and purpose of the treatment liquid. The contact time is practically 10 to 120 seconds, preferably 20 to 90 seconds and more preferably 30 to 60 seconds.

A drying step of drying the object to be treated may be performed after the above-described rinsing step.

Examples of the drying method include a spin drying method, a method of flowing a dry gas onto the object to be treated, a method of heating a substrate by a heating unit such as a hot plate and an infrared lamp, a Marangoni drying method, a Rotagoni drying method, an isopropyl alcohol (IPA) drying method, and a method of combining any of these methods.

### [Manufacturing Method of Semiconductor Device]

The cleaning method for the object to be treated described above can be suitably applied to a manufacturing method of a semiconductor device.

The above-described cleaning method may be performed in combination before or after other steps performed on a substrate. The above-described cleaning method may be incorporated into other steps while performing the cleaning method, or the above-described cleaning method may be incorporated into the other steps.

Examples of the other steps include a step of forming each structure such as a metal wire, a gate structure, a source structure, a drain structure, an insulating film, a ferromagnetic layer, and a non-magnetic layer (for example, layer formation, etching, chemical mechanical polishing, modification, or the like), a resist forming step, an exposure step and a removal step, a heat treatment step, a cleaning step, and an examination step.

The above-described cleaning method may be performed at any stage among the back-end process (BEOL: back end of the line), the middle process (MOL: middle of the line), and the front-end process (FEOL: front end of the line); and it is preferable that the treatment method be performed in a front-end process or a middle process.

### EXAMPLES

Hereinafter, the present invention will be described in more detail with reference to Examples.

The materials, the amounts and proportions of the materials used, the details of treatments, the procedure of treatments, and the like shown in the following Examples can be appropriately modified as long as the gist of the present invention is maintained. Therefore, the scope of the present invention should not be construed as being limited to Examples shown below.

In the following Examples, a pH of the treatment liquid was measured at 25° C. using a pH meter (manufactured by HORIBA, Ltd., model “F-74”) in accordance with JIS Z 8802-1984.

In addition, in production of treatment liquids of Examples and Comparative Examples, all of handling of a container, and production, filling, storage, and analytical measurement of the treatment liquids were performed in a clean room satisfying a level of ISO Class 2 or lower.

### [Preparation of Treatment Liquid]

The following compounds were used to produce a treatment liquid. As various components used in Examples, those all classified into a semiconductor grade or a high-purity grade equivalent thereto were used.

### [Quaternary Ammonium Compound]

A-1: tetramethylammonium hydroxide
A-2: ethyltrimethylammonium hydroxide
A-3: tetraethylammonium hydroxide
A-4: choline hydroxide

### [Tertiary Alkylamine Compound]

B-1: N,N,N′,N″,N″-pentamethyldiethylenetriamine
B-2: N,N,N′,N′-tetramethylethylenediamine
B-3: triethylamine
B-4: bis(2-dimethylaminoethyl)ether
B-5: N,N,N′,N′-tetramethylhexamethylenediamine
B-6: N-methyl-N′-(2-dimethylaminoethyl)piperazine
B-7: N-methylpiperidine
B-8: N,N-diisopropylethylamine
B-9: 2-(dimethylamino)-2-methyl-1-propanol
B-10: 3-hydroxy-1-methylpiperidine
B-11: N,N-dimethylaminoethoxyethanol
B-12: N,N-dimethylethylenediamine
B-13: tris(2-aminoethyl)amine

### [Heterocyclic Compound]

C-1: xanthine
C-2: adenine
C-3: adenosine

### [Other Additives]

D-1: succinic acid
D-2: etidronic acid
D-3: sulfuric acid
D-4: p-toluenesulfonic acid

The above-described compounds were mixed so as to have the formulations shown in Tables 1 and 2 in a case of being diluted 100 times by volume, and thus a concentrated solution was prepared. Next, the concentrated solution was diluted 100 times by volume with ultrapure water as a diluent to obtain treatment liquids of Examples and Comparative Examples, having the formulations shown in Tables 1 and 2. The obtained treatment liquid was stored at 40° C. for one month, and thus a treatment liquid to be used for evaluation of the treatment liquid after long-term storage was prepared.

A pH of the treatment liquids shown in Tables 1 and 2 was adjusted by adding hydrochloric acid as a pH adjuster as necessary.

In the treatment liquid, the remaining component (remainder) other than components specified as the components of the treatment liquid in the tables was ultrapure water and the pH adjuster. A content of the pH adjuster was 1% by mass or less in all of Examples.

### [Preparation of Polishing Liquid]

Each component was mixed at the proportions shown below, and thus a polishing liquid 1 and a polishing liquid 2 were prepared.

Polishing liquid 1 (pH: 7.0)

| | | |
|---|---|---|
| Colloidal silica (PL3, manufactured by | 0.1% | by mass |
| FUSO CHEMICAL CO., LTD.) | | |
| Glycine | 1.0% | by mass |
| 3-Amino-1,2,4-triazole | 0.2% | by mass |
| Benzotriazole (BTA) | 30 | ppm by mass |
| Hydrogen peroxide | 1.0% | by mass |
| pH adjuster (ammonia and nitric acid) | | |

| | |
|---|---|
| Water | remainder |

Polishing liquid 2 (pH: 10.5)

| | | |
|---|---|---|
| Colloidal silica (PL3, manufactured by | 6.0% | by mass |
| FUSO CHEMICAL CO., LTD.) | | |
| Citric acid | 1.0% | by mass |
| Alkylalkoxylate surfactant | 100 | ppm by mass |
| BTA | 0.2% | by mass |
| Hydrogen peroxide | 1.0% | by mass |
| pH adjuster (potassium hydroxide and nitric acid) | | |

| | |
|---|---|
| Water | remainder |

[Evaluation 1 of Treatment Liquid: Semiconductor Substrate after CMP]

Defect removability and surface roughness characteristic of the treatment liquid after long-term storage were evaluated by the following procedure.

### [Defect Removability]

A Cu-patterned wafer was prepared by forming a TaN film having a thickness of 5 nm and a Ta film having a thickness of 5 nm in this order on a substrate in which MIT 754 pattern of an insulating film (Black Diamond film, manufactured by AMAT) was formed on a silicon wafer having a diameter of 300 mm by a PVD method, and further forming a Cu film having a thickness of 1,500 nm by an electrolytic plating method.

The above-described Cu-patterned wafer was polished using FREX300S-II (polishing device, manufactured by EBARA CORPORATION) and the polishing liquid 1 as a polishing liquid. As polishing conditions, an in-plane average value of a polishing pressure was set to 105 hPa, a supply rate of the polishing liquid was set to 200 mL/min, and the polishing was performed until the end point of the polishing was detected, and then the polishing was further performed for 30 seconds.

Next, the Cu-patterned wafer subjected to the above-described polishing treatment was further polished under conditions in which a polishing liquid 2 was used as a polishing liquid, an in-plane average value of a polishing pressure was 70 hPa, a supply rate of the polishing liquid was 200 mL/min, and a polishing time was 60 seconds.

The obtained Cu-patterned wafer subjected to the CMP treatment was subjected to scrub cleaning for 1 minute using the treatment liquid of Examples and Comparative Examples, adjusted to room temperature (23° C.), and then subjected to a drying treatment.

Thereafter, a defect detection device (ComPlus-II, manufactured by AMAT) was used to measure the number of detections of signal intensities corresponding to defects having a length of more than 0.1 μm on the obtained polished surface of the wafer.

From the obtained number of defects of more than 0.1 μm, the defect removability was evaluated according to the following evaluation standard.
A: number of defects of more than 0.1 μm was 500 or less.
B: number of defects of more than 0.1 μm was 501 to 1,000.
C: number of defects of more than 0.1 μm was 1,001 to 3,000.
D: number of defects of more than 0.1 μm was 3,001 or more.

### [Surface Roughness Characteristic]

A TaN film having a thickness of 5 nm and a Ta film having a thickness of 5 nm were formed in this order on a silicon wafer having a diameter of 300 mm by a PVD method. Furthermore, a Cu wafer was prepared by forming a Cu film having a thickness of 1,500 nm by an electrolytic plating method.

Using FREX300S-II (polishing device, manufactured by EBARA CORPORATION), the prepared Cu wafer was polished under conditions in which the polishing liquid 1 was used as a polishing liquid, an in-plane average value of a polishing pressure was 105 hPa, a supply rate of the polishing liquid was 200 mL/min, and a polishing time was 30 seconds. Next, the Cu wafer subjected to the above-described polishing treatment was further polished under conditions in which a polishing liquid 2 was used as a polishing liquid, an in-plane average value of a polishing pressure was 70 hPa, a supply rate of the polishing liquid was 200 mL/min, and a polishing time was 60 seconds.

The obtained Cu wafer subjected to the CMP treatment was subjected to scrub cleaning for 1 minute using the treatment liquid of Examples and Comparative Examples, adjusted to room temperature (23° C.), and then subjected to a drying treatment.

Thereafter, any 10 μm×10 μm region of the polished surface of the obtained wafer was scanned with an atomic force microscope (AFM; AFM NanoNavi Real, manufactured by Hitachi High-Tech Corporation) to calculate a surface roughness Ra.

From the obtained Ra value, the surface roughness characteristic after long-term storage of each treatment liquid after long-term storage was evaluated according to the following evaluation standard. As the value of the surface roughness Ra was smaller, the surface roughness could be reduced more, which is preferable.
A: surface roughness Ra was less than 1 nm.
B: surface roughness Ra was 1 nm or more and 2 nm or less.
C: surface roughness Ra was more than 2 nm.

### Result

The formulations of the treatment liquids of Examples and the evaluation results are shown in Table 1 and Table 2.

In the tables, the column of “Content (% by mass” indicates the content (% by mass) of each component with respect to the total mass of the treatment liquid.

In the tables, the numerical value in the column of pH indicates the pH of the treatment liquid at 25° C., which was measured by the above-described pH meter.

In the tables, the numerical value in the column of “A/C” indicates a mass ratio of the content (A) of the quaternary ammonium compound to the content (C) of the heterocyclic compound (Content (A) of quaternary ammonium compound/Content (C) of heterocyclic compound).

In the tables, the numerical value in the column of “B/C” indicates a mass ratio of the content (B) of the tertiary alkylamine compound to the content (C) of the heterocyclic compound (Content (B) of tertiary alkylamine compound/Content (C) of heterocyclic compound).

TABLE 1

| | A) Quaternary | | | | | | | | | | | | | | |
|---|---|---|---|---|---|---|---|---|---|---|---|---|---|---|---|
| | ammonium | | | | | | C) Heterocyclic | | D) Other | | | | | | |
| | compound | | B) Tertiary alkylamine compound | | | | compound | | components | | | | | | |
| | | Content | | Content | | Content | | Content | | Content | | | | | |
| | | (% by | | (% by | | (% by | | (% by | | (% by | | | | Defect | Surface |
| | Type | mass) | Type | mass) | Type | mass) | Type | mass) | Type | mass) | pH | A/C | B/C | removability | roughness |
| Example 1 | A-1 | 0.0150 | B-1 | 0.0150 | — | — | C-1 | 0.0005 | — | — | 11.3 | 30.0 | 30.0 | A | A |
| Example 2 | A-2 | 0.0200 | B-6 | 0.0200 | — | — | C-2 | 0.0008 | — | — | 11.2 | 25.0 | 25.0 | B | A |
| Example 3 | A-3 | 0.0200 | B-7 | 0.0500 | — | — | C-1 | 0.0010 | — | — | 11.4 | 20.0 | 50.0 | B | A |
| Example 4 | A-3 | 0.0100 | B-5 | 0.0500 | — | — | C-1 | 0.0012 | — | — | 11.4 | 8.3 | 41.7 | B | B |
| Example 5 | A-3 | 0.0100 | B-2 | 0.0200 | — | — | C-2 | 0.0010 | — | — | 10.9 | 10.0 | 20.0 | B | A |
| Example 6 | A-1 | 0.0300 | B-8 | 0.0200 | — | — | C-2 | 0.0001 | — | — | 11.5 | 300.0 | 200.0 | A | B |
| Example 7 | A-2 | 0.0200 | B-1 | 0.0300 | — | — | C-2 | 0.0001 | — | — | 11.3 | 200.0 | 300.0 | A | B |
| Example 8 | A-3 | 0.0150 | B-4 | 0.0150 | — | — | C-1 | 0.0010 | — | — | 11.2 | 15.0 | 15.0 | B | A |
| Example 9 | A-1 | 0.0200 | B-1 | 0.0200 | B-9 | 0.0100 | C-2 | 0.0010 | — | — | 11.1 | 20.0 | 30.0 | A | A |
| Example 10 | A-2 | 0.0200 | B-3 | 0.0200 | — | — | C-3 | 0.0010 | — | — | 11.2 | 20.0 | 20.0 | A | A |
| Example 11 | A-2 | 0.0100 | B-1 | 0.0100 | B-10 | 0.0500 | C-2 | 0.0005 | — | — | 11.3 | 20.0 | 120.0 | A | B |
| Example 12 | A-3 | 0.0100 | B-5 | 0.0050 | B-11 | 0.1000 | C-1 | 0.0010 | — | — | 11.2 | 10.0 | 105.0 | A | A |
| Example 13 | A-2 | 0.0100 | B-1 | 0.0500 | — | — | C-1 | 0.0010 | — | — | 11.1 | 10.0 | 50.0 | A | A |
| Example 14 | A-1 | 0.1000 | B-2 | 0.1000 | — | — | C-1 | 0.0100 | — | — | 11.7 | 10.0 | 10.0 | A | A |
| Example 15 | A-1 | 0.0020 | B-2 | 0.0020 | — | — | C-1 | 0.0001 | — | — | 11.0 | 20.0 | 20.0 | B | A |
| Example 16 | A-3 | 0.0150 | B-1 | 0.0100 | B-7 | 0.0100 | C-3 | 0.0010 | — | — | 11.3 | 15.0 | 20.0 | A | A |
| Example 17 | A-3 | 0.0200 | B-1 | 0.0300 | — | — | C-2 | 0.0005 | — | — | 11.2 | 40.0 | 60.0 | A | A |
| Example 18 | A-2 | 0.0200 | B-5 | 0.0100 | — | — | C-2 | 0.0001 | — | — | 11.3 | 200.0 | 100.0 | A | A |
| Example 19 | A-1 | 0.0150 | B-2 | 0.0100 | B-1 | 0.0500 | C-2 | 0.0010 | — | — | 11.3 | 15.0 | 60.0 | A | A |
| Example 20 | A-2 | 0.0150 | B-3 | 0.0200 | B-12 | 0.0010 | C-2 | 0.0010 | — | — | 11.3 | 15.0 | 21.0 | A | A |
| Example 21 | A-1 | 0.0300 | B-2 | 0.0150 | B-13 | 0.0020 | C-1 | 0.0005 | — | — | 11.3 | 60.0 | 34.0 | A | A |

TABLE 2

| | A) Quaternary | | | | | | | | | | | | | | |
|---|---|---|---|---|---|---|---|---|---|---|---|---|---|---|---|
| | ammonium | | | | | | C) Heterocyclic | | D) Other | | | | | | |
| | compound | | B) Tertiary alkylamine compound | | | | compound | | components | | | | | | |
| | | Content | | Content | | Content | | Content | | Content | | | | | |
| | | (% by | | (% by | | (% by | | (% by | | (% by | | | | Defect | Surface |
| | Type | mass) | Type | mass) | Type | mass) | Type | mass) | Type | mass) | pH | A/C | B/C | removability | roughness |
| Example 22 | A-2 | 0.0200 | B-3 | 0.0200 | — | — | C-3 | 0.0010 | D-1 | 0.0050 | 11.1 | 20.0 | 20.0 | A | A |
| Example 23 | A-1 | 0.0200 | B-8 | 0.0100 | — | — | C-2 | 0.0003 | D-2 | 0.0050 | 11.0 | 66.7 | 33.3 | A | A |
| Example 24 | A-1 | 0.0200 | B-1 | 0.0200 | — | — | C-2 | 0.0010 | — | — | 9.5 | 20.0 | 20.0 | B | B |
| Example 25 | A-2 | 2.0000 | B-3 | 2.0000 | — | — | C-3 | 0.1000 | — | — | 12.1 | 20.0 | 20.0 | A | A |
| Example 26 | A-2 | 1.0000 | B-1 | 1.0000 | B-10 | 0.0500 | C-2 | 0.0600 | — | — | 12.0 | 16.7 | 17.5 | A | B |
| Example 27 | A-2 | 0.0200 | B-1 | 0.0400 | — | — | C-2 | 0.0001 | — | — | 11.3 | 200.0 | 400.0 | A | B |
| Example 28 | A-3 | 5.0000 | B-3 | 2.0000 | — | — | C-1 | 0.1000 | — | — | 12.3 | 50.0 | 20.0 | A | A |
| Example 29 | A-1 | 1.0000 | B-2 | 1.0000 | — | — | C-1 | 0.1000 | — | — | 12.0 | 10.0 | 10.0 | A | A |
| Example 30 | A-2 | 0.0200 | B-1 | 0.0100 | — | — | C-2 | 0.0005 | D-3 | 0.0010 | 11.3 | 40.0 | 20.0 | A | A |
| Example 31 | A-2 | 0.0150 | B-1 | 0.0200 | — | — | C-2 | 0.0005 | D-4 | 0.0010 | 11.3 | 30.0 | 40.0 | A | A |
| Example 32 | A-2 | 0.0200 | B-1 | 0.0200 | — | — | C-1 | 0.0005 | — | — | 11.3 | 20.0 | 20.0 | A | A |
| | | | | | | | C-2 | 0.0005 | | | | | | | |
| Example 33 | A-2 | 0.0200 | B-1 | 0.0200 | — | — | C-2 | 0.0005 | — | — | 11.5 | 80.0 | 40.0 | A | A |
| | A-3 | 0.0200 | | | | | | | | | | | | | |
| Comparative | — | — | B-1 | 0.0500 | — | — | C-1 | 0.0005 | — | — | 9.8 | — | 100.0 | D | B |
| Example 1 | | | | | | | | | | | | | | | |
| Comparative | A-2 | 0.0150 | — | — | — | — | C-2 | 0.0001 | — | — | 11.1 | 150.0 | — | D | A |
| Example 2 | | | | | | | | | | | | | | | |
| Comparative | A-3 | 0.0200 | B-2 | 0.0100 | — | — | — | — | — | — | 11.4 | — | — | A | C |
| Example 3 | | | | | | | | | | | | | | | |
| Comparative | A-4 | 0.0160 | B-5 | 0.0200 | — | — | C-3 | 0.0005 | — | — | 11.2 | 32.0 | 40.0 | C | A |
| Example 4 | | | | | | | | | | | | | | | |
| Comparative | A-2 | 0.0200 | B-3 | 0.0300 | — | — | C-3 | 0.0050 | — | — | 11.0 | 4.0 | 6.0 | C | A |
| Example 5 | | | | | | | | | | | | | | | |
| Comparative | A-2 | 0.0200 | B-3 | 0.0500 | — | — | C-1 | 0.0001 | — | — | 11.0 | 200.0 | 500.0 | A | C |
| Example 6 | | | | | | | | | | | | | | | |
| Comparative | A-3 | 0.0200 | B-5 | 2.0000 | — | — | C-1 | 0.3000 | — | — | 11.3 | 0.1 | 6.7 | C | A |
| Example 7 | | | | | | | | | | | | | | | |

From the above tables, it was found that the treatment liquid according to the embodiment of the present invention could reduce the surface roughness of a metal and had excellent defect removability even in a case where the treatment liquid was applied onto the object to be treated containing a metal, which had been subjected to a chemical mechanical polishing treatment, after being stored for a long period of time.

From the comparison between Examples 2 and 3 and other examples, it was found that the effect of the present invention was more excellent in a case where the tertiary alkylamine compound did not have a cyclic structure.

From the comparison between Example 8 and other examples, it was found that the effect of the present invention was more excellent in a case where the tertiary alkylamine compound did not have an ether bond.

From the comparison between Examples 4 to 7 and other examples, it was found that the effect of the present invention was more excellent in a case where the mass ratio of the quaternary ammonium compound having no hydroxyl group to the content of the heterocyclic compound was 10 or more.

From the comparison between Example 6 and other examples, it was found that the effect of the present invention was more excellent in a case where the mass ratio of the quaternary ammonium compound having no hydroxyl group to the content of the heterocyclic compound was 200 or less.

From the comparison between Examples 6, 7, and 27 and other examples, it was found that the effect of the present invention was more excellent in a case where the mass ratio of the tertiary alkylamine compound to the content of the heterocyclic compound was 150 or less.

From the comparison between Example 15 and other examples, it was found that the effect of the present invention was more excellent in a case where the content of the quaternary ammonium compound was 0.005% by mass or more with respect to the total mass of the treatment liquid.

From the comparison between Example 15 and other examples, it was found that the effect of the present invention was more excellent in a case where the content of the tertiary alkylamine compound was 0.005% by mass or more with respect to the total mass of the treatment liquid.

From the comparison between Example 24 and other examples, it was found that the effect of the present invention was more excellent in a case where the pH of the treatment liquid was 10.0 or more.

As a result of performing the tests according to the evaluation procedures described in [Defect removability] and [Surface roughness characteristic] above, except that Cu of the object to be treated was changed to Co, the same evaluation results were obtained.

[Evaluation 2 of Treatment Liquid: Semiconductor Substrate after Pad Cleaning Treatment]

A wafer was prepared according to the procedure described in [Evaluation 1 of treatment liquid: semiconductor substrate after CMP] for [Defect removability] and [Surface roughness characteristic] above, and subjected to a CMP treatment.

The polished surface of the wafer subjected to the CMP treatment was subjected to a pad cleaning treatment under the following conditions using FREX300S-II (polishing device, manufactured by EBARA CORPORATION).

| Table rotation speed: | 80 | rpm |
|---|---|---|
| Head rotation speed: | 78 | rpm |
| In-plane average value of pad pressure: | 138 | hPa |
| Polishing pad: | IC1400 manufactured | |
| | by Rodel-Nitta | |
| Composition for pad cleaning: | treatment liquid used | |
| | in Example 1 | |
| Supply rate of composition for pad cleaning: | 250 | mL/min |
| Polishing time: | 20 | seconds |

The obtained wafer subjected to the pad cleaning treatment was subjected to scrub cleaning for 1 minute using the treatment liquid used in Example 1, adjusted to room temperature (23° C.), and then subjected to a drying treatment. Thereafter, in a case where the evaluation of [Defect removability] and [Surface roughness characteristic] was carried out according to the procedures described in [Evaluation 1 of treatment liquid: semiconductor substrate after CMP], the same evaluation results as those of Example 1 were obtained.

Even in a case where the treatment liquids used in Examples 2 to 33 were used instead of the treatment liquid used in Example 1, the same evaluation results as the evaluation results of each example in the evaluation 1 of the treatment liquid were obtained.

What is claimed is:

1. A treatment liquid used for an object to be treated, which has been subjected to a chemical mechanical polishing treatment, the treatment liquid comprising:
a quaternary ammonium compound having no hydroxyl group;
a tertiary alkylamine compound;
a heterocyclic compound; and
water,
wherein the tertiary alkylamine compound includes at least one or more tertiary alkylamine compounds having no hydroxyl group, and
a mass ratio of a content of the tertiary alkylamine compound to a content of the heterocyclic compound is 10 to 400.

2. The treatment liquid according to claim 1,
wherein a mass ratio of a content of the quaternary ammonium compound having no hydroxyl group to the content of the heterocyclic compound is 10 to 300.

3. The treatment liquid according to claim 1,
wherein a pH is 10.0 to 14.0.

4. The treatment liquid according to claim 1,
wherein the treatment liquid substantially contains no abrasive particles.

5. The treatment liquid according to claim 1,
wherein the tertiary alkylamine compound has no cyclic structure.

6. The treatment liquid according to claim 1,
wherein the tertiary alkylamine compound has no oxygen atom.

7. The treatment liquid according to claim 1,
wherein the heterocyclic compound includes at least one selected from the group consisting of a purine compound, imidazole, pyrazole, thiazole, triazole, tetrazole, piperazine, pyrrole, indole, carbazole, quinoline, piperidine, pyridine, imidazoline, pyrimidine, and triazine.

8. The treatment liquid according to claim 1,
wherein the object to be treated, which has been subjected to a chemical mechanical polishing treatment, includes at least one metal selected from the group consisting of copper and cobalt.

9. A cleaning method for an object to be treated, comprising:
a step of cleaning an object to be treated, which has been subjected to a chemical mechanical polishing treatment, using the treatment liquid according to claim 1.

10. A manufacturing method of an electronic device, comprising:
the cleaning method for an object to be treated according to claim 9.

11. The treatment liquid according to claim 2,
wherein a pH is 10.0 to 14.0.

12. The treatment liquid according to claim 2,
wherein the treatment liquid substantially contains no abrasive particles.

13. The treatment liquid according to claim 2,
wherein the tertiary alkylamine compound has no cyclic structure.

14. The treatment liquid according to claim 2,
wherein the tertiary alkylamine compound has no oxygen atom.

15. The treatment liquid according to claim 2,
wherein the heterocyclic compound includes at least one selected from the group consisting of a purine compound, imidazole, pyrazole, thiazole, triazole, tetrazole, piperazine, pyrrole, indole, carbazole, quinoline, piperidine, pyridine, imidazoline, pyrimidine, and triazine.

16. The treatment liquid according to claim 2,
wherein the object to be treated, which has been subjected to a chemical mechanical polishing treatment, includes at least one metal selected from the group consisting of copper and cobalt.

17. A cleaning method for an object to be treated, comprising:
a step of cleaning an object to be treated, which has been subjected to a chemical mechanical polishing treatment, using the treatment liquid according to claim 2.

18. A manufacturing method of an electronic device, comprising:
the cleaning method for an object to be treated according to claim 17.

19. The treatment liquid according to claim 3,
wherein the treatment liquid substantially contains no abrasive particles.

20. The treatment liquid according to claim 3,
wherein the tertiary alkylamine compound has no cyclic structure.
